(19) United States
(12) Patent Application Publication
(10) Pub. No.: US 2026/0303129 A1
(43) Pub. Date: Oct. 1, 2026

(54) MULTIMODE VARIABLE LOW INTERMEDIATE FREQUENCY (VLIF) RADIO ARCHITECTURE

(71) Applicant: QUALCOMM INCORPORATED, San Diego, CA (US)

(72) Inventors: Ojas CHOKSI, San Diego, CA (US); Wu-Hsin CHEN, San Diego, CA (US)

(21) Appl. No.: 19/090,970

(22) Filed: Mar. 26, 2025

(51) Int. Cl. H04B 1/00; H03L 7/08; H04B 1/40

(52) U.S. Cl. CPC H04B 1/0075; H03L 7/08; H04B 1/40

(57) ABSTRACT

A variable low intermediate frequency (VLIF), millimeter wave (mmW) communication system includes a receive section having a receive radio frequency (RF) conversion stage, the receive RF conversion stage configured to convert a receive communication signal between RF and a first receive IF using a first local oscillator (LO1) signal generated by an integer-N phase locked loop (PLL) circuit, a receive variable intermediate frequency (IF) conversion stage, the receive variable IF conversion stage configured to convert the first receive IF signal to a first receive variable low IF (VLIF) signal using a second local oscillator (LO2) signal generated by one of the integer-N PLL circuit or a fractional-N phase locked loop (PLL) circuit, and a third conversion stage configured to convert the first receive variable low IF (VLIF) signal to a near-baseband signal using a third local oscillator (LO3) signal generated by a second fractional-N PLL circuit.

### FIELD

The present disclosure relates generally to electronics, and more specifically to an intermediate frequency (IF) architecture in a transceiver.

### BACKGROUND

Wireless communication devices and technologies are becoming ever more prevalent, as are communication devices that operate at millimeter-wave (mmW) and sub-terahertz (subTHz) frequencies. Wireless communication devices generally transmit and/or receive communication signals. In a radio frequency (RF) transceiver, a communication signal is typically amplified and transmitted by a transmit section and a received communication signal is amplified and processed by a receive section. A transceiver for communication in 5G and 6G applications generally communicates using millimeter wave (mmW) frequency signals and sub-THz frequencies.

Transceivers used in some 5G communication systems generally use what is referred to as a superheterodyne (or Superhet) architecture, where a millimeter-wave radio frequency (RF) signal of, for example, approximately 24 gigahertz (GHz) to approximately 48 GHz received at a first integrated circuit (mmW-IC) is first downconverted to an intermediate frequency (IF), and the IF signal is then transferred to another IC where it is downconverted to baseband. Challenges with such an architecture include, for example, multiple different frequency translations (for example, from RF to IF and then from IF to baseband), which consumes valuable circuit area, and the need to transfer the IF signal from the mmW IC to another IC. Typically, these IF signals are transferred using IF cables. Such cables can be costly and may lead to signal loss. In some architectures, complex filtering is also needed to provide desired signal characteristics, reject jammer signals (jammers) and provide anti-aliasing. Further, the cost in circuit area becomes greater when new advanced process nodes are considered.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides a variable low intermediate frequency (VLIF), millimeter wave (mmW) communication system including a receive section having a receive radio frequency (RF) conversion stage, the receive RF conversion stage configured to convert a receive communication signal between RF and a first receive IF using a first local oscillator (LO1) signal generated by an integer-N phase locked loop (PLL) circuit, a receive variable intermediate frequency (IF) conversion stage, the receive variable IF conversion stage configured to convert the first receive IF signal to a first receive variable low IF (VLIF) signal using a second local oscillator (LO2) signal generated by one of the integer-N PLL circuit or a fractional-N phase locked loop (PLL) circuit, and a third conversion stage configured to convert the first receive variable low IF (VLIF) signal to a near-baseband signal using a third local oscillator (LO3) signal generated by a second fractional-N PLL circuit.

Another aspect of the disclosure provides a method for processing communication signals including converting, at a millimeter wave integrated circuit (mmW-IC), a receive communication signal between RF and a first receive IF using a first local oscillator (LO1) signal generated by an integer-N phase locked loop (PLL) circuit, converting, at the mmW-IC, the first receive IF signal to a first receive variable low IF (VLIF) signal using a second local oscillator (LO2) signal generated by a fractional-N phase locked loop (PLL) circuit, and converting, in an intermediate frequency integrated circuit (IFIC) the first receive variable low IF (VLIF) signal using a third local oscillator (LO3) signal generated by a second fractional-N phase locked loop (PLL) circuit.

Another aspect of the disclosure provides a communication system including a radio frequency (RF) receive section having a plurality of RF receive paths, each RF receive path having an RF conversion stage and an intermediate frequency (IF) conversion stage, the RF receive section capable of downconverting a receive signal using one or more of the plurality of RF receive paths, wherein a first PLL provides a first LO signal and a second PLL provides a second LO signal, the first LO signal comprising an RF conversion frequency and the second LO signal comprising a very low intermediate frequency (VLIF) conversion frequency, and an IF receive section having a plurality of IF receive paths, each IF receive path having a baseband conversion stage, the IF receive section capable of downconverting the receive signal using one or more of the plurality of IF receive paths, wherein a third PLL provides a third LO signal, the third LO signal comprising a near-baseband conversion frequency.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system.

FIG. 2A is a block diagram showing a wireless device in which exemplary techniques of the present disclosure may be implemented

FIG. 2B is a block diagram showing a wireless device in which exemplary techniques of the present disclosure may be implemented.

FIG. 2C is a block diagram showing a wireless device in which exemplary techniques of the present disclosure may be implemented.

FIG. 3 is a block diagram of a receive portion of a millimeter wave integrated circuit (mmW-IC) and an intermediate frequency integrated circuit (IFIC) in accordance with an exemplary embodiment of the disclosure.

FIG. 4 is a block diagram of a transmit portion of a millimeter wave integrated circuit (mmW-IC) and an intermediate frequency integrated circuit (IFIC) in accordance with an exemplary embodiment of the disclosure.

FIG. 5 is a block diagram of a receive portion of a millimeter wave integrated circuit (mmW-IC) and an intermediate frequency integrated circuit (IFIC) in accordance with an exemplary embodiment of the disclosure.

FIG. 6 is a graphical illustration showing signal bandwidth and local oscillator (LO) signals for the single band (LB in this example) shown in FIG. 5.

FIG. 7 is a block diagram of a receive portion of a millimeter wave integrated circuit (mmW-IC) and an intermediate frequency integrated circuit (IFIC) in accordance with an exemplary embodiment of the disclosure.

FIG. 8 is a graphical illustration showing signal bandwidth and local oscillator (LO) signals for the single band (LB in this example) shown in FIG. 7.

FIG. 9 is a block diagram of a receive portion of a millimeter wave integrated circuit (mmW-IC) and an intermediate frequency integrated circuit (IFIC) in accordance with an exemplary embodiment of the disclosure.

FIG. 10 is a graphical illustration showing signal bandwidth and local oscillator (LO) signals for the single band (MB/HB in this example) shown in FIG. 9.

FIG. 11 is a block diagram 1100 of a receive portion of a millimeter wave integrated circuit (mmW-IC) and an intermediate frequency integrated circuit (IFIC) in accordance with an exemplary embodiment of the disclosure.

FIG. 12 is a graphical illustration showing signal bandwidth and local oscillator (LO) signals for the single band (MB/HB in this example) shown in FIG. 11.

FIG. 13 is a block diagram of a receive portion of a millimeter wave integrated circuit (mmW-IC) and an intermediate frequency integrated circuit (IFIC) in accordance with an exemplary embodiment of the disclosure.

FIG. 14 is a graphical illustration showing signal bandwidth and local oscillator (LO) signals for the single band (LB in this example) downconverted over two Rx chains in mmW IC, shown in FIG. 13.

FIG. 15 is a block diagram of a receive portion of a millimeter wave integrated circuit (mmW-IC) and an intermediate frequency integrated circuit (IFIC) in accordance with an exemplary embodiment of the disclosure.

FIG. 16 is a graphical illustration showing signal bandwidth and local oscillator (LO) signals for the single band (LB in this example) downconverted over two Rx chains shown in FIG. 15.

FIG. 17 is a block diagram of a receive portion of a millimeter wave integrated circuit (mmW-IC) and an intermediate frequency integrated circuit (IFIC) in accordance with an exemplary embodiment of the disclosure.

FIG. 18 is a graphical illustration showing signal bandwidth and local oscillator (LO) signals for the interband carrier aggregation (CA) (LB+MB in this example) signal having a bandwidth smaller than the maximum signal path bandwidth shown in FIG. 17.

FIG. 19 is a block diagram of a receive portion of a millimeter wave integrated circuit (mmW-IC) and an intermediate frequency integrated circuit (IFIC) in accordance with an alternative exemplary embodiment of the disclosure.

FIG. 20 is a block diagram of a receive portion of a millimeter wave integrated circuit (mmW-IC) and an intermediate frequency integrated circuit (IFIC) in accordance with an alternative exemplary embodiment of the disclosure.

FIG. 21 is a block diagram of a receive portion of a millimeter wave integrated circuit (mmW-IC) and an intermediate frequency integrated circuit (IFIC) in accordance with an alternative exemplary embodiment of the disclosure.

FIG. 22 is a flow chart describing an example of the operation of a method for signal conversion.

FIG. 23 is a functional block diagram of an apparatus for signal conversion.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In accordance with an exemplary embodiment, a variable low intermediate frequency (VLIF) radio architecture may reduce millimeter-wave (mmW) overhead by reducing the number of phase locked loop (PLL) circuits used to convert a radio frequency (RF) signal to a very low intermediate frequency (VLIF) signal in the millimeter wave integrated circuit (MMW-IC).

In accordance with an exemplary embodiment, a variable low intermediate frequency (VLIF) radio architecture reduces design complexity in an IFIC by allowing the use of advanced semiconductor processing technologies for the IFIC.

In accordance with an exemplary embodiment, a variable low intermediate frequency (VLIF) radio architecture allows IF cables between a mmW-IC and an IFIC to carry low band and mid band/high-band signals while providing isolation between the IF cables.

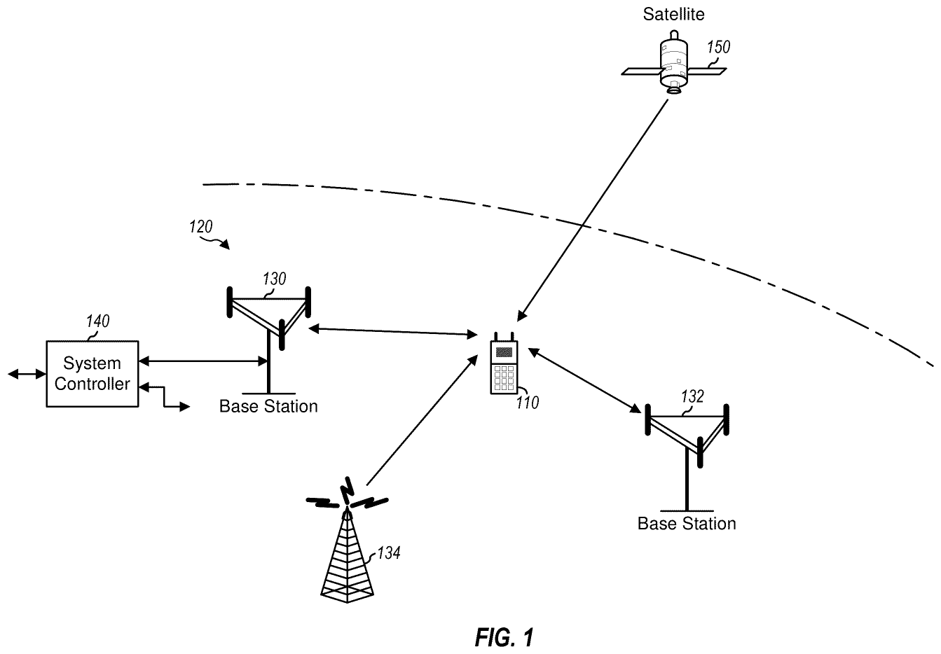

FIG. 1 is a diagram showing a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, a 5G NR (new radio) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, an automobile, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134) and/or signals from satellites (e.g., a satellite 150 in one or more global navigation satellite systems (GNSS)), etc.). Wireless device 110 may support one or more radio technologies for wireless communication such as LTE, WCDMA, CDMA 1X, EVDO, TD-SCDMA, GSM, 802.11, 802.15, 5G-NR, FMCW, 6G, UWB, etc., for FR1, 5G FR 2, FR2-2, FR 3, and D-band frequencies.

Wireless device 110 may support carrier aggregation (CA), for example as described in one or more LTE or 5G standards. In some embodiments, a single stream of data is transmitted over multiple carriers using carrier aggregation, for example as opposed to separate carriers being used for respective data streams. Wireless device 110 may be able to operate in a variety of communication bands including, for example, those communication bands used by LTE, WiFi, 5G or other communication bands, over a wide range of frequencies. Wireless device 110 may also be capable of communicating directly with other wireless devices without communicating through a network.

In general, carrier aggregation may be categorized into two types-intra-band CA and inter-band CA. Intra-band CA refers to operation on multiple carriers within the same band. Inter-band CA refers to operation on multiple carriers in different bands.

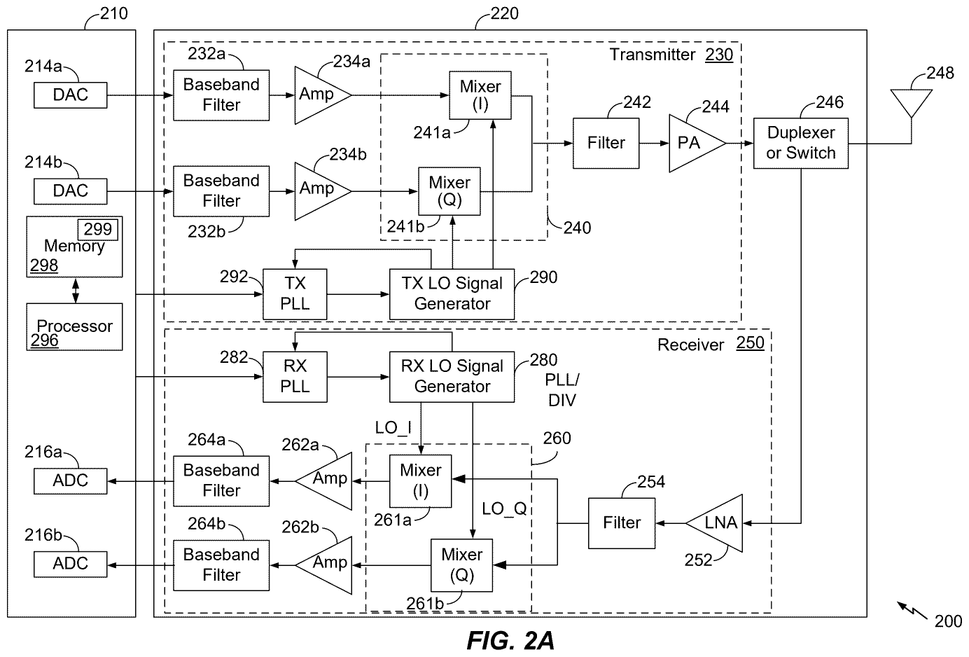

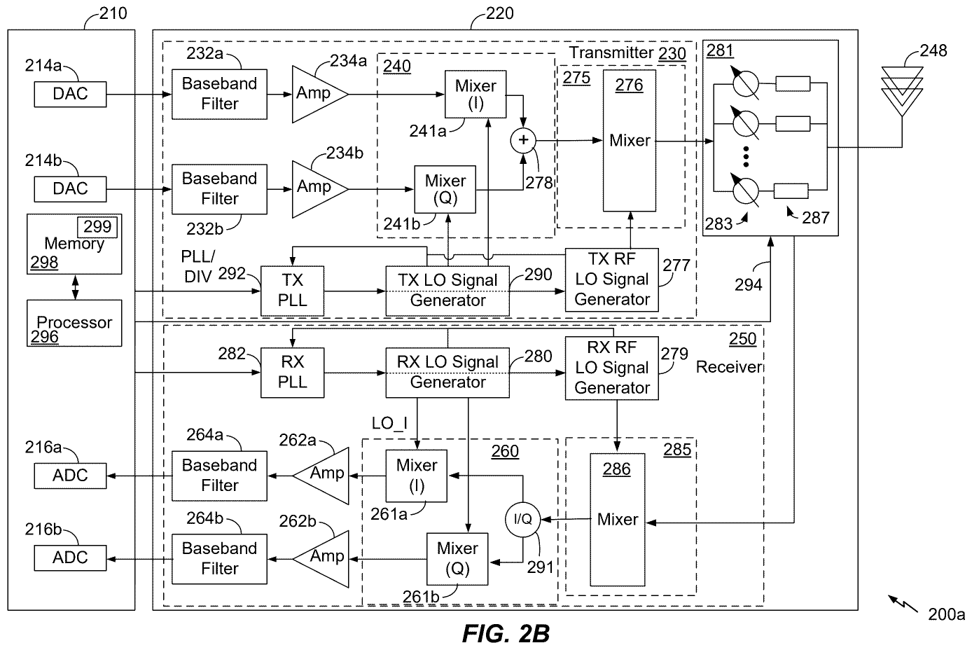

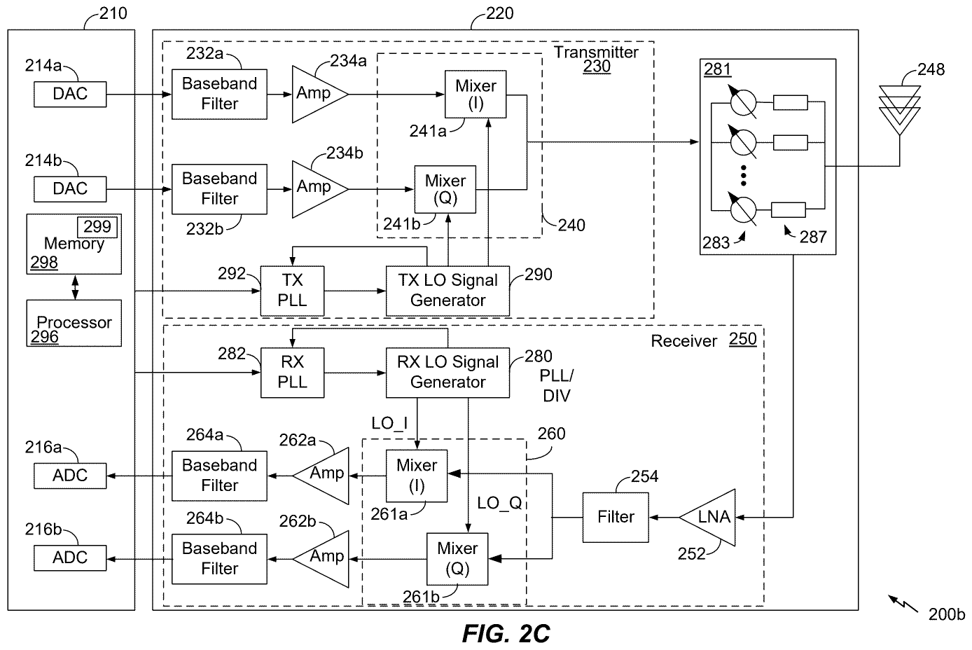

FIG. 2A is a block diagram showing a wireless device 200 in which exemplary techniques of the present disclosure may be implemented. The wireless device 200 may, for example, be an embodiment of the wireless device 110 illustrated in FIG. 1.

FIG. 2A shows an example of a transceiver 220 having a transmitter 230 and a receiver 250. In general, the conditioning of the signals in the transmitter 230 and the receiver 250 may be performed by one or more stages of amplifier, filter, upconverter, downconverter, etc. These circuit blocks may be arranged differently from the configuration shown in FIG. 2A. Furthermore, other circuit blocks not shown in FIG. 2A may also be used to condition the signals in the transmitter 230 and receiver 250. Unless otherwise noted, any signal in FIG. 2A, or any other figure in the drawings, may be either single-ended or differential. Some circuit blocks in FIG. 2A may also be omitted.

In the example shown in FIG. 2A, wireless device 200 generally comprises the transceiver 220 and a data processor 210. The data processor 210 may include a processor 296 operatively coupled to a memory 298. The memory 298 may be configured to store data and program codes shown generally using reference numeral 299, and may generally comprise analog and/or digital processing components. The processor 296 and the memory 298 may cooperate to control, configure, program, or otherwise fully or partially control some or all of the operation of the embodiments of the variable low IF circuits described herein.

The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 2A, transmitter 230 and receiver 250 are implemented with the direct-conversion architecture.

In the transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, baseband (e.g., lowpass) filters 232a and 232b filter the I and Q analog transmit signals, respectively, to remove undesired images caused by the prior digital-to-analog conversion. Amplifiers (Amp) 234a and 234b amplify the signals from baseband filters 232a and 232b, respectively, and provide I and Q baseband signals. An upconverter 240 having upconversion mixers 241a and 241b upconverts the I and Q baseband signals with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier (PA) 244 amplifies the signal from filter 242 to obtain the desired output power level and provides a transmit RF signal. The transmit RF signal may be routed through a duplexer or switch 246 and transmitted via an antenna 248. While examples discussed herein utilize I and Q signals, those of skill in the art will understand that components of the transceiver may be configured to utilize polar modulation.

In the receive path, antenna 248 receives communication signals and provides a received RF signal, which may be routed through duplexer or switch 246 and provided to a low noise amplifier (LNA) 252. The duplexer 246 is designed to operate with a specific RX-to-TX duplexer frequency separation, such that RX signals are isolated from TX signals. The received RF signal is amplified by LNA 252 and filtered by a filter 254 to obtain a desired RF input signal.

Downconversion mixers 261a and 261b in a downconverter 260 mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by baseband (e.g., lowpass) filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2A, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain components of the transceiver 220 are functionally illustrated in FIG. 2A, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules, chips, and/or components. For example, the power amplifier 244, the filter 242, and the duplexer 246 may be implemented in separate modules or as discrete components, while the remaining components illustrated in the transceiver 220 may be implemented in a single transceiver chip.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more driver stages, one or more power amplifier stages, one or more impedance matching networks, and can be configured to provide good linearity, efficiency, or a combination of good linearity and efficiency.

In an exemplary embodiment in a super-heterodyne architecture, the PA 244 and LNA 252 (and filter 242 and filter 254 in some examples) may be implemented separately from other components in the transmitter 230 and receiver 250, for example on a millimeter wave integrated circuit. An example super-heterodyne architecture is illustrated in FIG. 2B.

FIG. 2B is a block diagram showing a wireless device in which exemplary techniques of the present disclosure may be implemented. In an exemplary embodiment, FIG. 2B shows a wireless device that uses a beam forming heterodyne (or superheterodyne) architecture for a phased array time domain duplex (TDD) system.

Certain components, for example which may be indicated by identical reference numerals, of the wireless device 200a in FIG. 2B may be configured similarly to those in the wireless device 200 shown in FIG. 2A and the description of identically numbered items in FIG. 2B will not be repeated.

The wireless device 200a is an example of a heterodyne (or superheterodyne) architecture in which the upconverter 240 and the downconverter 260 are configured to process a communication signal between baseband and an intermediate frequency (IF). The IF signal may be a low IF (LIF) signal, or a zero (or near zero) IF (ZIF) signal. For example, the upconverter 240 may include a summing function 278 and may be configured to provide an IF signal to an upconverter 275. In an exemplary embodiment, the upconverter 275 may comprise upconversion mixer 276. The summing function 278 combines the I and the Q outputs of the upconverter 240 and provides a non-quadrature signal to the mixer 276. The non-quadrature signal may be single ended or differential. The mixer 276 is configured to receive the IF signal from the upconverter 240 and TX RF LO signals from a TX RF LO signal generator 277, and provide an upconverted RF signal to phase shift circuitry 281. While PLL 292 is illustrated in FIG. 2B as being shared by the signal generators 290, 277, a respective PLL for each signal generator may be implemented.

In an exemplary embodiment, components in the phase shift circuitry 281 may comprise one or more adjustable or variable phased array elements, and may receive one or more control signals from the data processor 210 over connection 294 and operate the adjustable or variable phased array elements based on the received control signals.

In an exemplary embodiment, the phase shift circuitry 281 comprises phase shifters 283 and phased array elements 287. Although three phase shifters 283 and three phased array elements 287 are shown for ease of illustration, the phase shift circuitry 281 may comprise more or fewer phase shifters 283 and phased array elements 287.

Each phase shifter 283 may be configured to receive the RF transmit signal from the upconverter 275, alter the phase by an amount, and provide the RF signal to a respective phased array element 287. Each phased array element 287 may comprise transmit and receive circuitry including one or more filters, amplifiers, driver amplifiers, and/or power amplifiers. In some embodiments, the phase shifters 283 may be incorporated within respective phased array elements 287.

The output of the phase shift circuitry 281 is provided to an antenna array 248. In an exemplary embodiment, the antenna array 248 comprises a number of antennas that typically correspond to the number of phase shifters 283 and phased array elements 287, for example such that each antenna element is coupled to a respective phased array element 287. In an exemplary embodiment, the phase shift circuitry 281 and the antenna array 248 may be referred to as a phased array.

In a receive direction, an output of the phase shift circuitry 281 is provided to a downconverter 285. In an exemplary embodiment, the downconverter 285 may comprise a downconversion mixer 286. In an exemplary embodiment, the mixer 286 downconverts the receive RF signal provided by the phase shift circuitry 281 to an IF signal according to RX RF LO signals provided by an RX RF LO signal generator 279. The downconverter 260 includes an I/Q generation function 291. The I/Q generation function 291 receives the IF signal from the mixer 286 and generates I and Q signals for the downconverter 260, which downconverts the IF signals to baseband, as described above. While PLL 282 is illustrated in FIG. 2B as being shared by the signal generators 280, 279, a respective PLL for each signal generator may be implemented.

In some embodiments, the upconverter 275, downconverter 285, and the phase shift circuitry 281 are implemented on a common IC (e.g., the mmW-IC described below). In some embodiments, the summing function 278 and the I/Q generation function 291 are implemented separate from the mixers 276 and 286 such that the mixers 276, 286 and the phase shift circuitry 281 are implemented on the common IC, but the summing function 278 and I/Q generation function 291 are not (e.g., the summing function 278 and I/Q generation function 291 are implemented in another IC, for example the IFIC described below, coupled to the IC having the mixers 276, 286). In some embodiments, the LO signal generators 277, 279 are included in the common IC. In some embodiments in which phase shift circuitry is implemented on a common IC with 276, 286, 277, 278, 279, and/or 291, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate. Some configurations described above may be able to be improved in terms of circuit area and/or signal loss, for example as introduced over a cable. Some examples described below may improve upon these aspects and may promote the implementation of relevant circuitry in smaller process nodes.

In some embodiments, both the architecture illustrated in FIG. 2A and the architecture illustrated in FIG. 2B are implemented in the same device. For example, a wireless device 110 or 200 may be configured to communicate with signals having a frequency below about 20 GHz using the architecture illustrated in FIG. 2A and to communicate with signals having a frequency above about 20 GHz using the architecture illustrated in FIG. 2B. In devices in which both architectures are implemented, one or more components of FIGS. 2A and 2B that are identically numbered may be shared between the two architectures. For example, both signals that have been downconverted directly to baseband from RF and signals that have been downconverted from RF to baseband via an IF stage may be filtered by the same baseband filter 264. In other embodiments, a first version of the filter 264 is included in the portion of the device which implements the architecture of FIG. 2A and a second version of the filter 264 is included in the portion of the device which implements the architecture of FIG. 2B. While certain example frequencies are described herein, other implementations are possible. For example, signals having a frequency above about 20 GHz (e.g., having a mmW frequency) may be transmitted and/or received using a direct conversion architecture. In such embodiments, for example, a phased array may be implemented in the direct conversion architecture.

FIG. 2C is a block diagram showing a wireless device in which exemplary techniques of the present disclosure may be implemented. Certain components, for example which may be indicated by identical reference numerals, of the wireless device 200b in FIG. 2C may be configured similarly to those in the wireless device 200 shown in FIG. 2A and/or the wireless device 200a shown in FIG. 2B and the description of identically numbered items in FIG. 2C will not be repeated.

The wireless device 200b in FIG. 2C incorporates the phase shift circuitry 281 (of FIG. 2B) in a direct conversion architecture, where mmW transmission signals are upconverted and downconverted between baseband and RF without the use of intermediate frequency (IF) signal conversion. For example, the LO signals in the architecture of FIG. 2C may comprise signals at frequencies of tens of GHz.

In some embodiments, the upconverter 240, downconverter 260, and the phase shift circuitry 281 are implemented on a common IC. In some embodiments, the LO signal generators 280, 290 are included in the common IC. In some embodiments, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate.

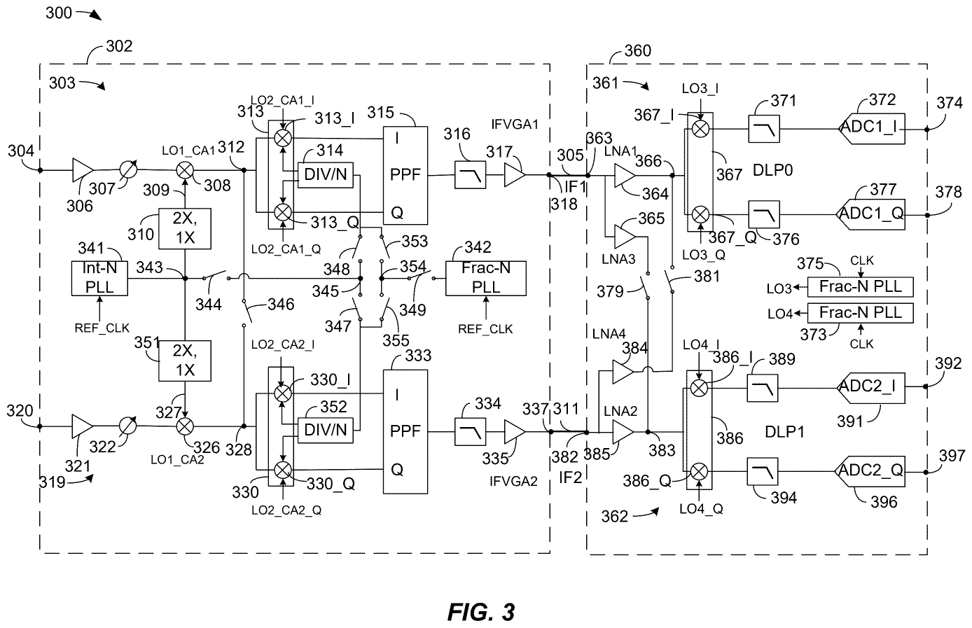

FIG. 3 is a block diagram 300 of a receive portion of a millimeter wave integrated circuit (mmW-IC) and an intermediate frequency integrated circuit (IFIC) in accordance with an exemplary embodiment of the disclosure. In an exemplary embodiment, a millimeter wave integrated circuit (mmW-IC) 302 may be connected to an intermediate frequency integrated circuit (IFIC) 360 via one or more IF cables 305 and 311. In an alternate example, a transceiver architecture may use complex filtering and a real (non-complex) analog-to-digital converter (ADC) to process communication signals and filter jammers. Complex filtering causes high power consumption when passing very wide bandwidth signals and consumes significant circuit area due to the many active transistor devices used for filtering. Further, complex filtering also requires accurate Q/pole tuning, droop/band flatness and residual sideband (RSB) calibration. Complex filters are also very sensitive to parasitics. Further, ADCs used in such architectures need very high sampling rates to process the wide bandwidth signals at VLIF frequency and are generally not scalable for wider bandwidths. In addition, when multiple time-interleaved ADCs are used to realize high sampling rates (Fs), Fs/2 and Fs/4 spurs due to timing mismatch can appear in band or in the aliasing zone, degrading the signal-to-noise ratio (SNR). Further, for interband CA, the signals on each cable generally need high isolation as they are not offset in frequencies. In an exemplary embodiment, the circuit shown in FIG. 3 uses a polyphase filter (PPF) and real low pass filtering along with a third signal downconversion in the IFIC to overcome many of these drawbacks. This allows for a relatively simple PPF (thus avoiding complex filters) in the mmW IC and a third signal down conversion in the IFIC to DC while using a real LPF, thus reducing ADC bandwidth and helps improve spur performance when time-interleaved cores are used for the ADC to achieve high sample rates, etc. Using an integer-N PLL 341 in the mmW IC and fractional-N PLLs 373 and 375 in the IFIC 360 improves IPN (integrated phase noise) due to uncorrelated noise, solves phase alignment issues across different mmW modules used in a large phased array, due to the use of the integer-N PLL 341 and reduces the likelihood that spurs will cause interference. A fractional-N PLL does not retain the phase when it is turned to low power/micro-sleep modes and retuned after wakeup. Also, this exemplary embodiment, improves IF cable isolation as the third downconversion (in the IFIC 360) allows non-overlapping frequencies of IF signal for interband CA. The fractional-N-PLLs 373 and 375 used in the IFIC 360 for the third downconversion provide flexibility in achieving fine frequency resolution and dodges spurious signals, especially for interband CA operation. As will be described below, the architecture shown in FIG. 3 allows for single band signal downconversion or for interband CA. In an exemplary embodiment and as will be described below, a common “LO1” and a common “LO2” are implemented to reduce the number of PLLs from four to two for interband CA signal processing. In an exemplary embodiment, the LO signals described herein are illustrated using single lines for convenience. The LO signals described herein may be single-ended or differential signals.

In an exemplary embodiment, the mmW-IC 302 may comprise a number of receive paths and a number of transmit paths. However, only the receive paths will be described in FIG. 3. Exemplary receive paths are shown using reference numerals 303 and 319. In an exemplary embodiment, the mmW-IC 302 may comprise an integer-N frequency synthesizer, referred to as an integer-N phase locked loop (PLL) 341 and a fractional-N frequency synthesizer, referred to as a fractional-N PLL 342. In an exemplary embodiment, the integer-N PLL 341 may be configured to receive a clock signal (REF_CLK) and generate whole number frequency local oscillator (LO_) signals. In an exemplary embodiment, the fractional-N PLL 342 may be configured to receive a clock signal (REF_CLK) and generate fractional number frequency local oscillator (LO_) signals. In an exemplary embodiment, the receive path 303 and the receive path 319 are designed for a certain bandwidth (BW), B. When the signal bandwidth is <B, the signal is downconverted over a single receive path, such as receive path 303/361 or receive path 319/362. When the signal bandwidth is >B, the signal is downconverted over two receive paths, such as receive path 303/361 and receive path 319/362.

The integer-N PLL 341 may be connected to a node 343 and the fractional-N PLL 342 may be connected to a node 354 through a switch 349. A switch 344 may be connected between the node 343 and the node 345. A switch 353 may be connected between the node 354 and a divider 314.

In an exemplary embodiment, a receive path 303 may include a port 304. In an exemplary embodiment, while shown as a single element the port 304 may comprise multiple ports that may be coupled to one or more antennas, or may be coupled through a switching system (not shown) to one or more antennas. In an exemplary embodiment, the port 304 is shown as coupled to a low noise amplifier (LNA) 306 and the LNA 306 is shown as coupled to a phase shifter (PS) 307. Similar to the port 304, the LNA 306 and the PS 307 are shown as single elements, but may comprise multiple LNAs and multiple phase shifters. In some embodiments, signals from multiple antennas, LNAs and phase shifters may be combined in a combiner (not shown) after the PS 307 and provided to a mixer 308. The phase shift circuitry 281 of FIGS. 2B and 2C may be an example implementation of the port 304, LNA 306 and phase shifter 307.

The PS 307 may be coupled to a mixer 308. In an exemplary embodiment, the mixer 308 may comprise a real mixer (i.e., not a complex I/Q mixer) and may comprise a first downconverter, a first downconverter stage, or a receive RF conversion stage, and may be configured to downconvert a radio frequency (RF) signal provided by the PS 307 to a lower frequency. In an exemplary embodiment, the RF input signal to the mixer 308 may be at a millimeter wave (mmW) frequency of, for example, 24-48 gigahertz (GHz). In an exemplary embodiment, the mixer 308 may be configured to receive a local oscillator (LO) signal (LO1) over connection 309 from the integer-N PLL 341 through a multiplier 310, which then provides the LO signal over connection 309 to the mixer 308. In an exemplary embodiment, the mixer 308 may be configured to convert the mmW RF signal from the PS 307 to an intermediate frequency (IF) in the range of, for example, 4-12GHz. The IF signal at an approximate frequency of 4-12GHz may be referred to as a first IF signal. In an exemplary embodiment, the LO1 signal on connection 309 may be an integer LO signal and the mixer 308 may perform integer downconversion.

In an exemplary embodiment, the signal from the real mixer 308 is provided to a downconverter 313 at a node 312. In an exemplary embodiment, the downconverter 313 may comprise an in-phase mixer 313_I and a quadrature mixer 313_Q. In an exemplary embodiment, the downconverter 313 may comprise a second downconverter, a second downconverter stage, or a receive variable low intermediate frequency (VLIF) conversion stage and may be configured to downconvert the first IF signal provided by the mixer 308 to a first variable low intermediate frequency (VLIF).

In an exemplary embodiment, the divider 314 may be connected to the node 345 through a switch 348 and may be connected to the node 354 through a switch 353. In an exemplary embodiment, when the switches 353 and 349 are conductive, the fractional-N PLL 342 may provide a local oscillator signal (LO2) to the divider 314. The divider 314 may provide an LO2_CA1_I local oscillator signal to the mixer 313_I and may provide an LO2_CA1_Q local oscillator signal to the mixer 313_Q. The term “CA” refers to “carrier aggregation” and may signify that multiple RF carriers may be processed by the mmW-IC 302.

The LO2 signals provided by the divider 314 may be used by the downconverter 313 to downconvert the 4-12 GHz IF signal from the mixer 308 to a first variable intermediate frequency (IF), referred to herein as a first variable low intermediate frequency (VLIF) signal. In an exemplary embodiment, the first variable low intermediate frequency (VLIF) signal may have a frequency on the order of approximately 300 MHz to approximately 1100 MHz depending on bandwidth and VLIF offset chosen. In another exemplary embodiment, the mixer 308 may be configured to directly downconvert the RF signal to a VLIF signal of approximately 300 MHz to approximately 1100 MHz. In such an exemplary embodiment, the divider 314 and downconverter 313 may be omitted. In some examples, converting between low IF and RF in two stages (for example pursuant to some configurations described herein) reduces the phase noise and I/Q balance requirements on the synthesizer.

The downconverter 313 also performs a quadrature operation on the (real) output of the mixer 308 so that the output of the downconverter 313 is a complex signal, for example, a quadrature signal having an in phase (I) signal component and a quadrature (Q) signal component. The I and Q signals may be differential. If the downconverter 313 is omitted in a direct conversion architecture, then the mixer 308 would perform the downconversion and the I/Q signal generation. In some embodiments, one or more buffer amplifiers may be used between the mixer 308 and the downconverter 313.

In an exemplary embodiment, the output of the downconverter 313 is provided to a polyphase filter (PPF) 315. The PPF 315 converts the complex I and Q signals from the downconverter 313 to a real differential signal. The real differential signal is provided to a low pass filter 316 that allows signals of a desired frequency to pass while filtering in-band jammers falling outside of the VLIF range. The order of the low pass filter 316 depends on the isolation achieved between the adjacent port in the IFIC that may be downconverting a different frequency band in an adjacent signal path as the downconverted jammers may desensitize that frequency band. In an exemplary embodiment, the low pass filter 316 may be a real low pass filter and may be implemented using fewer active devices (such as operational amplifiers) because a real low pass filter (active or passive) is easier to implement than a complex filter that may require many operational amplifiers (opamps), frequency response tuning and calibrations.

The output of the low pass filter 316 is provided to an intermediate frequency (IF) variable gain amplifier (VGA) 317. The IF VGA 317 amplifies the signal from the low pass filter 316, performs differential to single ended conversion, and provides the amplified IF signal to a node 318. The node 318 may be an example of a port and/or pin, or other component or interface to the cable 305.

In an exemplary embodiment, a receive path 319 is similar to the receive path 303. In an exemplary embodiment, the receive path 319 may include a port 320. In an exemplary embodiment, while shown as a single element the port 320 may comprise multiple ports that may be coupled to one or more antennas, or may be coupled through a switching system to one or more antennas. In some examples, the port 304 may be coupled to a different band than the port 320. For example, the port 304 may be a low band (LB) port and the port 320 may be used for another band (mid or high band (MB/HB).

In some examples, the ports 304 and 320 are coupled to respective antennas configured for operation with different frequencies. In an exemplary embodiment, the port 320 is shown as coupled to a low noise amplifier (LNA) 321 and the LNA 321 is shown as coupled to a phase shifter (PS) 322. Similar to the port 320, the LNA 321 and the PS 322 are shown as single elements, but may comprise multiple LNAs and multiple phase shifters. In some embodiments, signals from multiple antennas, LNAs and phase shifters may be combined in a combiner (not shown) after the PS 322 and provided to a mixer 326. The phase shift circuitry 281 of FIGS. 2B and 2C may be an example implementation of the port 320, LNA 321 and phase shifter 322. In an exemplary embodiment, the receive path 303 and the receive path 319 may be configured for single input, single output (SISO) operation or multiple input, multiple output (MIMO) operation.

The PS 322 may be coupled to a mixer 326. In an exemplary embodiment, the mixer 326 may comprise a real mixer and may comprise a first downconverter, a first downconverter stage, or a receive RF conversion stage and may be configured to downconvert a radio frequency signal provided by the PS 322 to a first intermediate frequency. In an exemplary embodiment, the RF input signal to the mixer 326 may be at a millimeter wave (mmW) frequency of, for example, 24-48 gigahertz (GHz). In an exemplary embodiment, the mixer 326 may be configured to receive a local oscillator (LO) signal (LO1) over connection 327 from the integer-N PLL 341 through a multiplier 351, which then provides the LO signal over connection 327 to the mixer 326. In an exemplary embodiment, the mixer 326 may be configured to convert the mmW RF signal from the PS 322 to a frequency in the range of, for example, 4-12GHz. This signal in the range of approximately 4-12 GHz may be referred to as a first IF signal. In an exemplary embodiment, the LO1 signal on connection 327 may be an integer LO signal and the mixer 326 may perform integer downconversion.

In an exemplary embodiment, the signal from the mixer 326 is provided to a downconverter 330 at a node 328. A switch 346 may be connected between the node 312 and the node 328 to allow a signal processed by the mixer 308 to be further processed by the downconverter 330, or to allow a signal processed by the mixer 326 to be further processed by the downconverter 313. For example, in a condition where a single bandwidth for example 1600 MHz of contiguous bandwidth may be downconverted, the signal can be divided across two I/Q mixers (downconverters 313 and 330), with each downconverting 800 MHz of the 1600 MHz bandwidth.

In an exemplary embodiment, the downconverter 330 may comprise an in-phase mixer 330_I and a quadrature mixer 330_Q. In an exemplary embodiment, the downconverter 330 may comprise a second downconverter, a second downconverter stage, or a second RX VLIF conversion stage and may be configured to downconvert the first IF signal provided by the mixer 326 to a first variable low intermediate frequency. In an exemplary embodiment, the first variable low intermediate frequency (VLIF) signal may have a frequency on the order of approximately 300 MHz to approximately 1100 MHz (depending on bandwidth and VLIF offset chosen).

In an exemplary embodiment, a divider 352 may be connected to the node 345 through a switch 347 and may be connected to the node 354 through a switch 355. In an exemplary embodiment, when the switches 355 and 349 are conductive, the fractional-N PLL 342 may provide a local oscillator signal (LO2) to the divider 352. The divider 352 may provide an LO2_CA2_I local oscillator signal to the mixer 330_I and may provide an LO2_CA2_Q local oscillator signal to the mixer 330_Q. The switches 344, 346, 347, 348, 353, 355 and 349 may be controlled by the data processor 210 (FIGS. 2B, 2C), or by another controller.

The LO2 signals provided by the divider 352 may be used by the downconverter 330 to downconvert the 4-12 GHz IF signal from the mixer 326 to a first variable intermediate frequency (IF), referred to herein as a first variable low intermediate frequency (VLIF) signal. In an exemplary embodiment, the first variable low intermediate frequency (VLIF) signal may have a frequency on the order of approximately 300 MHz to approximately 1100 MHz (depending on bandwidth and VLIF offset chosen). In another exemplary embodiment, the mixer 326 may be configured to directly downconvert the RF signal to a VLIF signal of approximately 300-1100 MHz. In such an exemplary embodiment, the divider 352 and downconverter 330 may be omitted. In some examples, converting between low IF and RF in two stages (for example pursuant to some configurations described herein) reduces noise.

The downconverter 330 also performs a quadrature operation on the real output of the mixer 326 so that the output of the downconverter 330 is a complex signal, for example, a quadrature signal having an in phase (I) signal component and a quadrature (Q) signal component. The I and Q signals may be differential. If the downconverter 330 is omitted in a direct conversion architecture, then the mixer 326 would perform the downconversion and the I/Q signal generation.

In an exemplary embodiment, the output of the downconverter 330 is provided to a polyphase filter (PPF) 333. The PPF 333 converts the complex I and Q signals from the downconverter 3130 to a real differential signal. The real differential signal is provided to a real low pass filter 334 that allows signals of a desired frequency to pass and to suppress jammers. The output of the low pass filter 334 is provided to an intermediate frequency (IF) variable gain amplifier (VGA) 335. The IF VGA 335 amplifies the signal from the low pass filter 334, performs differential to single ended conversion, and provides the amplified IF signal to a node 337. The node 337 may be an example of a port and/or pin, or other component or interface to the cable 311.

In an exemplary embodiment in interband CA, one of a low band (LB) and/or mid-band/high-band (MB/HB) signal may be provided to the receive path 303 and another of a LB or MB/HB signal may be provided to the receive path 319 simultaneously. In an exemplary embodiment, using a common source of LO1 (integer-N PLL 341) for both the receive path 303 and the receive path 319, and using a common source of LO2 (fractional-N PLL 342) for both the receive path 303 and the receive path 319 allows only two PLLs to be used in the mmW-IC 302. Moreover, independently selecting the LO1 and the LO2 frequency allows agility to avoid undesired spurious signals. Some alternate receiver architectures that support interband CA use four phase locked loop (PLL) circuits (two for integer-N LO signal generation and two for fractional-N LO signal generation). However, four PLLs consume significant die area, and may create unwanted spurious signals. The use of a fractional-N PLL for a single band operation may create phase alignment issues between mmW modules in a large phased-array system when the PLL is powered down during micro sleep and powered back up. In an exemplary embodiment, the architecture described herein shares the integer-N PLL 341 and the fractional-N PLL 342 between multiple receive paths to reduce die area and spurious signal generation. Locating the integer-N PLL 341 and the fractional-N PLL 342 as shown in FIG. 3 allows the different bands processed by the receive path 303 and the receive path 319 to be downconverted simultaneously.

In an exemplary embodiment, the IFIC 360 may include a receive path 361 and a receive path 362. In an exemplary embodiment, the receive path 361 may include a node 363 coupled to the IF cable 305. The node 363 may be an example of a port and/or pin, or other component or interface to the cable 305. In an exemplary embodiment, the signal at the node 363 is a single-ended real signal at a VLIF (variable low intermediate frequency) having a frequency on the order of approximately 300 MHz to approximately 1100 MHz (depending on bandwidth and VLIF offset chosen).

A low noise amplifier (LNA) 364 and an LNA 365 are also connected to the node 363. An output of the LNA 364 is provided to a node 366 and an output of the LNA 365 is provided to one side of a switch 379. One side of another switch 381 is connected to the node 366.

The node 366 is also connected to a downconverter 367. The downconverter 367 may comprise an in-phase mixer 367_I and a quadrature mixer 367_Q. An output of the mixer 367_I is provided to a baseband filter 371 and an output of the mixer 367_Q is provided to a baseband filter 376. In an exemplary embodiment, the mixer 367_I is configured to receive a local oscillator signal LO3_I and the mixer 367_Q is configured to receive a local oscillator signal LO3_Q. In an exemplary embodiment, the LO3_I and LO3_Q signals may be provided by a fractional-N PLL 375. In an exemplary embodiment, the LO4_I and LO4_Q signals may be provided by a fractional-N PLL 373. The fractional-N PLL 375 and the fractional-N PLL 373 may receive a clock signal (CLK). In an exemplary embodiment, the clock signal (REF_CLK) provided to the integer-N PLL 341 and the fractional-N PLL 342 in the mmW-IC 302 is a different clock signal than the reference clock signal (CLK) provided to the fractional-N PLL 375 and the fractional-N PLL 373. In an exemplary embodiment, the downconverter 367 may be a third downconverter stage configured to convert the VLIF signal from the mmW-IC 302 to a baseband information signal. For example, for single band downconversion (LB or MB/HB) with 1600 MHz bandwidth, LO3 downconverts an 800 MHz portion and LO4 downconverts the other 800 MHz portion of the 1600 MHz bandwidth. For interband CA (LB+MB/HB), LO3 downconverts the LB signal and LO4 downconverts MB/HB signal. In an exemplary embodiment, having the fractional-N PLL 375 to provide LO3 and the fractional-N PLL 373 to provide LO4 to perform ZIF downconversion reduces the VLIF from 300MHz-1100MHz to −400 MHz-400 MHz. This reduces the bandwidth that the ADC supports and reduces ADC power consumption.

The baseband filter 371 provides an in-phase real signal to an ADC 372 and the baseband filter 376 provides a quadrature real signal to an ADC 377.

In an exemplary embodiment, using the downconverter 367 to downconvert the VLIF signal from the mmW-IC allows the elimination of a complex bandpass filter in the mmW-IC and simplifies the filtering in the mmW-IC. The signal provided by the downconverter 367 is at or near DC, so the baseband filter 371 can also be simplified. Because the third downconversion (downconverter 367) brings the VLIF signal from 300MHz-1100MHz to −400 MHz-400 MHz a real filter (371, 376) with reduced bandwidth (and power consumption) can be used to filter the signal from any out of band jammers and also provide anti-aliasing. Without the third downconversion (367), the VLIF signal is centered around 700 MHz (300 MHz-1100MHz) and requires a complex filter with accurately tuned frequency response over a wide bandwidth, to provide image rejection of IBB jammers as well as provide anti-alias filtering. Such wide bandwidth complex filters may also consume significant power.

The ADC 372 converts the analog signal from the baseband filter 371 to a digital signal and provides the digital signal to a node 374 for further signal processing. For example, the node 374 may be coupled to the data processor 210 (e.g., to a modem). The ADC 377 converts the analog signal from the baseband filter 376 to a digital signal and provides the digital signal to a node 378 for further signal processing. For example, the node 378 may be coupled to the data processor 210 (e.g., to a modem).

The operating frequency ADC Fs of the ADC 372 and the ADC 377 (and the operating frequency DAC Fs to be described below) is related to the frequency of the downconverted VLIF signal and will be described in greater detail below.

In an exemplary embodiment, the receive path 362 may include a node 382 coupled to the IF cable 311. The node 382 may be an example of a port and/or pin, or other component or interface to the cable 311. In an exemplary embodiment, the signal at the node 382 is a single-ended real signal at a VLIF (variable low intermediate frequency) having a frequency on the order of approximately 300 MHz to approximately 1100 MHz (depending on bandwidth and VLIF offset chosen).

An LNA 384 and an LNA 385 are also connected to the node 382. An output of the LNA 385 is provided to a node 383 and an output of the LNA 384 is provided to one side of the switch 381. One side the switch 379 is connected to the node 383. The switches 379 and 381 may be controlled by the data processor 210 (FIGS. 2B, 2C), or by another controller.

In some embodiments, when the switch 379 is conductive, an output of the LNA 365 may be provided to the node 383 while the LNA 385 is off. Similarly, in some embodiments, when the switch 381 is conductive, an output of the LNA 384 may be provided to the node 366 while the LNA 364 is off. The purpose of the switches 379 and 381 is to split the wideband (WB) signal over two downconversion paths (sometimes referred to as downlink pipes) to realize intra-band carrier aggregation. For example, an 800 MHz signal may be split into two 400 MHz signals. Narrowband (NB) paths use lower BBF BW and ADC rates, saving power. Further narrowband paths from other technologies (for example, 4G, 5GNR SUB 6 ) can be used for this 3^{rd} downconversion stage in a converged IC supporting mmW+various other technologies (for example, GSM, WCDMA, LTE, 5G-NR for FR1, FR2, FR3 frequencies).

The node 383 is also connected to a downconverter 386. The downconverter 386 may comprise an in-phase mixer 386_I and a quadrature mixer 386_Q. An output of the mixer 386_I is provided to a baseband filter 389 and an output of the mixer 386_Q is provided to a baseband filter 394. In an exemplary embodiment, the mixer 386_I is configured to receive a local oscillator signal LO4_I and the mixer 386_Q is configured to receive a local oscillator signal LO4_Q from the fractional-N PLL 373. The value of LO3 can be the same or different than the value of LO4, such as, for example, when downconverting a single band signal, LO3 and LO4 may be the same, but when downconverting different band signals, LO3 and LO4 may be different.

The baseband filter 389 provides an in-phase real signal to an ADC 391 and the baseband filter 394 provides a quadrature real signal to an ADC 396.

The ADC 391 converts the analog signal from the baseband filter 389 to a digital signal and provides the digital signal to a node 392 for further signal processing. For example, the node 392 may be coupled to the data processor 210 (e.g., to a modem). The ADC 396 converts the analog signal from the baseband filter 394 to a digital signal and provides the digital signal to a node 397 for further signal processing. For example, the node 397 may be coupled to the data processor 210 (e.g., to a modem).

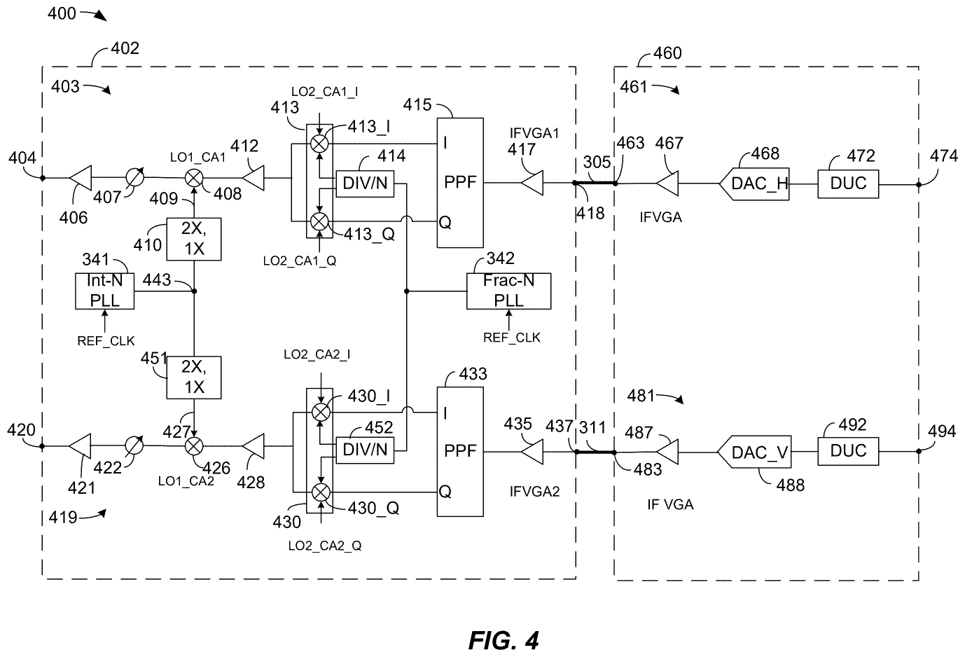

FIG. 4 is a block diagram 400 of a transmit portion of a millimeter wave integrated circuit (mmW-IC) and an intermediate frequency integrated circuit (IFIC) in accordance with an exemplary embodiment of the disclosure. In an exemplary embodiment, a millimeter wave integrated circuit (mmW-IC) 402 may be connected to an intermediate frequency integrated circuit (IFIC) 460 via one or more IF cables 305 and 311. In an exemplary embodiment, the millimeter wave integrated circuit (mmW-IC) 302 and the intermediate frequency integrated circuit (IFIC) 360 of FIG. 3 may be the same as the millimeter wave integrated circuit (mmW-IC) 402 and the intermediate frequency integrated circuit (IFIC) 460 of FIG. 4 and may share the IF cables 305 and 311. In some embodiments, a switching system (not shown) may allow the receive portion of FIG. 3 and the transmit portion of FIG. 4 to share the IF cables 305 and 311.

In an exemplary embodiment, a transmit path 403 includes an IFVGA 417 configured to perform single-ended to differential signal conversion for a transmit signal on node 418. In an exemplary embodiment, the signal provided over node 418 from the IFIC 460 may be referred to as a variable low intermediate frequency (VLIF) signal, and may be a second variable low IF signal. In an exemplary embodiment, the second variable low intermediate frequency (VLIF) signal may have a frequency on the order of approximately 300 MHz to approximately 1100 MHz (depending on bandwidth and VLIF offset chosen). In some embodiments, the first VLIF signal and the second VLIF signal may have the same frequency or may have different frequencies. The differential real signal provided by the IFVGA 417 is provided to a polyphase filter (PPF) 415. The PPF 415 converts the differential real signal to a differential quadrature signal having in phase (I) and quadrature (Q) signals. The I and Q signals are provided to an upconverter 413. In an exemplary embodiment, the upconverter 413 may include an in-phase mixer 413_I and a quadrature mixer 413_Q.

In an exemplary embodiment, the upconverter 413 receives an LO2 signal from a divider 414. The divider 414 receives the LO2 signal from the fractional-N PLL 342. The LO2 signal may be a differential signal. The divider 414 provides an LO2_CA1_I LO signal to the mixer 413_I and provides an LO2_CA1_Q LO signal to the mixer 413_Q.

In an exemplary embodiment, the upconverter 413 may be a first upconversion stage, or a TX VLIF conversion stage, configured to upconvert the second differential VLIF signal from the PPF 415 to a second IF signal having a frequency of, for example, 4-12 GHz.

In an exemplary embodiment, the output of the upconverter 413 is provided to an IFVGA 412. The amplified output of the IFVGA 412 is provided to a mixer 408. In an exemplary embodiment, the mixer 408 may be a second upconversion stage, or a TX RF conversion stage, configured to upconvert the second variable low IF signal from the IFVGA 412 to an RF frequency of, for example, 24-48 GHz according to the frequency of an LO1 signal provided over connection 409. In an exemplary embodiment, the integer-N PLL 341 provides an LO signal to a multiplier 410, which provides the LO1_CA1 LO signal to the mixer 408 over connection 409. If the mixer 408 is omitted in a direct conversion architecture, then the upconverter 413 would perform the upconversion to RF.

In an exemplary embodiment, the output of the mixer 408 is provided to a PS 407. The PS 407 applies a determined amount of phase shift and provides an output to a power amplifier (PA) 406. Although shown as a single element, the PA 406 may comprise one or more amplifier stages. The output of the PA 406 is provided to a port 404. Although shown as single elements, the PS 407, PA 406 and the port 404 may comprise multiple instances (e.g., coupled to a splitter (not shown) configured to split a signal from an output of the mixer 408 and provide it to multiple instances of the PS 407) where the port 404 may be connected to a switching system (not shown) similar to the ports 304 and 320 described above. In some embodiment, the port 404 may be connected through the switching system to the same antenna array as the ports 304 and 320.

In an exemplary embodiment, a transmit path 419 includes an IFVGA 435 configured to perform single-ended to differential signal conversion for a transmit signal on node 437. In an exemplary embodiment, the signal provided over node 437 from the IFIC 460 may be referred to as a variable low intermediate frequency (VLIF) signal, and may be a second variable low IF signal. In an exemplary embodiment, the second variable low intermediate frequency (VLIF) signal may have a frequency on the order of approximately 300 MHz to approximately 1100 MHz (depending on bandwidth and VLIF offset chosen). In some embodiments, the first VLIF signal and the second VLIF signal may have the same frequency or may have different frequencies. The real signal provided by the IFVGA 435 is provided to a polyphase filter (PPF) 433. The PPF 433 converts the differential real signal to a differential quadrature signal having in phase (I) and quadrature (Q) signals. The I and Q signals are provided to an upconverter 430. In an exemplary embodiment, the upconverter 430 may include an in-phase mixer 430_I and a quadrature mixer 430_Q.

In an exemplary embodiment, the upconverter 430 receives an LO2 signal from a divider 452. The divider 452 receives the LO2 signal from a fractional-N PLL 342. The divider provides an LO2_CA2_I LO signal to the mixer 430_I and provides an LO2_CA2_Q LO signal to the mixer 430_Q.

In an exemplary embodiment, the upconverter 430 may be a first upconversion stage, or a TX VLIF conversion stage, configured to upconvert a second VLIF signal from the PPF 433 to a second IF signal having a frequency of, for example, 4-12 GHz.

In an exemplary embodiment, the output of the upconverter 430 is provided to an IFVGA 428. The amplified output of the IFVGA 4128 is provided to a mixer 426. In an exemplary embodiment, the mixer 426 may be a second upconversion stage, or a TX RF conversion stage, configured to upconvert the second variable low IF signal from the IFVGA 428 to an RF frequency of, for example, 24-48 GHz according to the frequency of an LO1 signal provided over connection 427. In an exemplary embodiment, an integer-N PLL 341 provides an LO signal to a multiplier 451, which provides the LO1_CA2 LO signal to the mixer 426 over connection 427. If the mixer 426 is omitted in a direct conversion architecture, then the upconverter 430 would perform the upconversion to RF.

In an exemplary embodiment, the output of the mixer 426 is provided to a PS 422. The PS 422 applies a determined amount of phase shift and provides an output to a power amplifier (PA) 421. Although shown as a single element, the PA 421 may comprise one or more amplifier stages. The output of the PA 421 is provided to a port 420. Although shown as single elements, the PS 422, PA 421 and the port 420 may comprise multiple instances (e.g., coupled to a splitter (not shown) configured to split a signal from an output of the mixer 426 and provide it to multiple instances of the PS 422) where the port 420 may be connected to a switching system (not shown) similar to the ports 304 and 320 described above. In some embodiments, the port 420 may be connected through the switching system to the same antenna array as the ports 304 and 320 and may be coupled to operate with signals that have a different (e.g., orthogonal) polarization from signals associated with the port 404. The port 420 may alternatively or additionally be coupled to an antenna that is configured to operate at a frequency different than a frequency of operation of an antenna to which the port 404 is coupled. In another exemplary embodiment, the VLIF signal from the PPF 415 and the PPF 433 may be directly converted to an RF signal by the mixer 408 and the mixer 426, in which case the upconverters 413 and 430 and the dividers 414 and 452 would be omitted.

In an exemplary embodiment, the IFIC 460 may comprise a number of receive paths and a number of transmit paths. Exemplary transmit paths are shown using reference numerals 461 and 481.

In an exemplary embodiment, a transmit path 461 may include a node 474 coupled to a digital upconverter (DUC) 472. A transmit signal may be provided by a baseband element (e.g., the data processor 210, not shown) to the node 474 for upconversion and transmission. In an exemplary embodiment, the DUC 472 upconverts a baseband signal at node 474 to a VLIF signal. The VLIF signal output from the DUC 472 is provided to a DAC 468. The DAC 468 may be configured for a first (e.g., horizontal) polarization and converts the digital output of the DUC 472 to an analog real differential signal, which is provided to a differential to an IFVGA 467. The IFVGA 467 converts the differential signal from the DAC 468 to a single-ended signal and provides the single-ended signal to the node 463.

In an exemplary embodiment, a transmit path 481 may include a node 494 coupled to a digital upconverter (DUC) 492. A transmit signal may be provided by a baseband element (e.g., the data processor 210, not shown) to the node 494 for upconversion and transmission. In an exemplary embodiment, the DUC 492 upconverts a baseband signal at node 494 to a VLIF signal. The VLIF signal output from the DUC 492 is provided to a DAC 488. The DAC 488 may be configured for a second (e.g., vertical) polarization and converts the digital output of the DUC 492 to an analog real differential signal, which is provided to a differential to an IFVGA 487. The IFVGA 487 converts the differential signal from the RF-DAC 488 to a single-ended signal and provides the single-ended signal to the node 483.

In an exemplary embodiment, the DAC 468 and the DAC 488 may have an operating frequency (DAC Fs) that may be similar to the operating frequency of ADC Fs (on the order of 300 MHz to approximately 1100 MHz in an exemplary embodiment) or may be another operating frequency (on the order of 1.2 GHz to approximately 5.6 GHz or higher). The frequency ADC Fs and the frequency DAC Fs are related to the frequency of the VLIF signal.

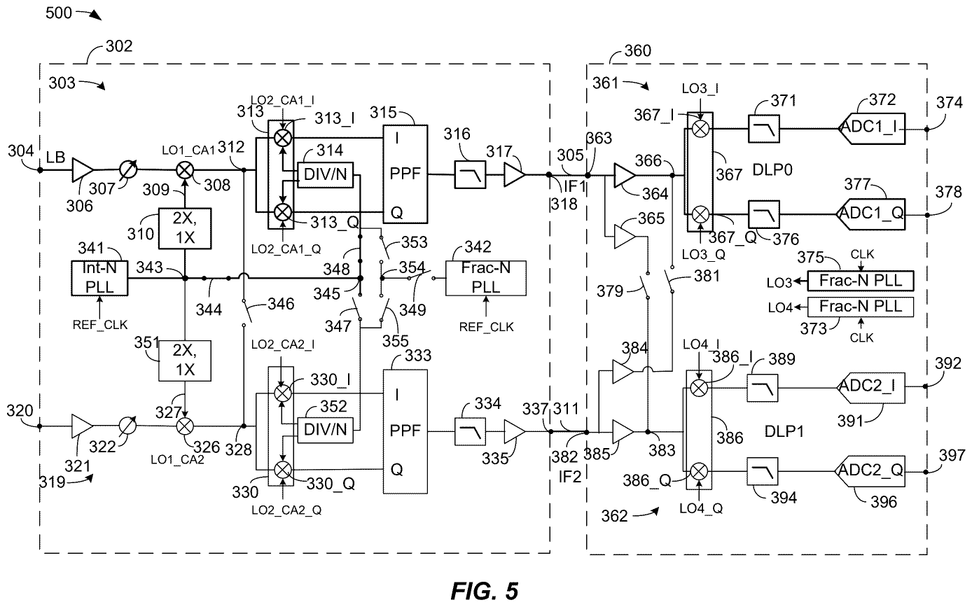

FIG. 5 is a block diagram 500 of a receive portion of a millimeter wave integrated circuit (mmW-IC) and an intermediate frequency integrated circuit (IFIC) in accordance with an exemplary embodiment of the disclosure. The configuration shown in FIG. 5 applies to an exemplary situation where the signal bandwidth is less than or equal to the maximum bandwidth supported by the downconversion path in the mmW-IC 302 and the IFIC 360. In this example, the elements in the mmW-IC 302 and the IFIC 360 that process a LB signal received at the port 304 are shown in bold line. In this example, the LB signal is applied to the LNA 306 and the PS 307 and downconverted by the mixer 308 using a local oscillator (LO) signal LO1_CA1 provided by the integer-N PLL 341 and the multiplier 310. The downconverter 313 further downconverts the signal using an LO signal LO2_CA1 (LO2_CA1_I and LO2_CA1_Q) provided by the integer-N PLL 341 and the divider 314. The signal is then processed by the PPF 315, low pass filter 316 and IF VGA 317 and provided to the IFIC 360 over the IF cable 305.

The receive signal is then processed by the LNA 364 and provided to the downconverter 367. The downconverter 367 receives an LO signal, LO3_I and LO3_Q from the fractional-N PLL 375. The downconverted in-phase and quadrature signals are then provided to the low pass filters 371 and 376 and to the ADCs 372 and 377 for further processing.

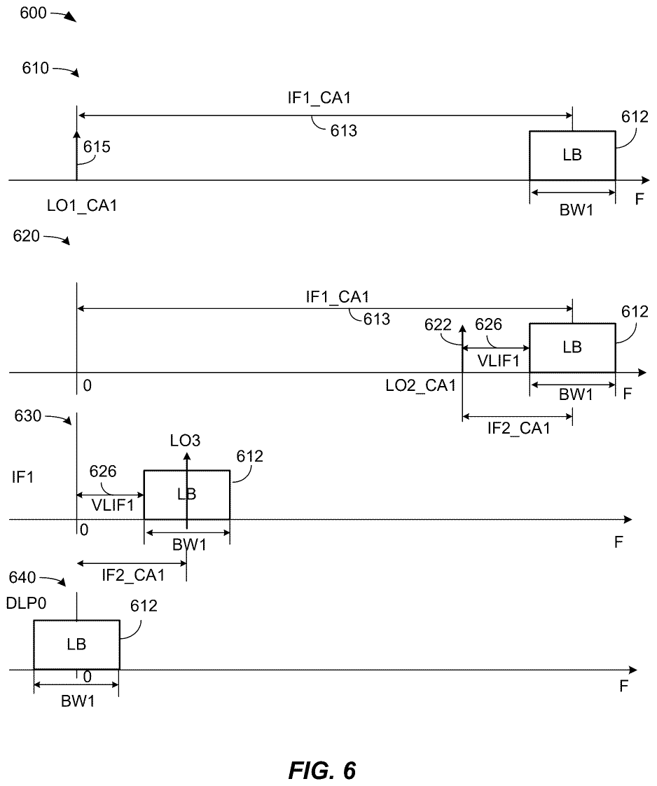

FIG. 6 is a graphical illustration 600 showing signal bandwidth and local oscillator (LO) signals for the single band (LB in this example) bandwidth smaller than the maximum bandwidth supported by the receive paths 303 and 361 shown in FIG. 5. FIG. 6 includes a graph 610 having a horizontal axis showing frequency increasing to the right. An exemplary first signal band 612 is shown as having a bandwidth of “BW1” and an exemplary LO signal, LO1_CA1 is shown using reference numeral 615. The exemplary signal IF1_CA1 613 denotes the first IF signal provided by the mixer 308.

In an exemplary embodiment, the graph 620 shows the first signal band 612 and also shows an LO signal, LO2_CA1 622, provided to the downconverter 313 by the integer-N PLL 341 (FIG. 5). The LO2_CA1 signal is located an offset of VLIF1 626 from the lower frequency of the first signal band 612. The distance from the center of the first signal band 612 to the LO2_CA1 LO signal is the second IF frequency, IF2_CA1, which is the VLIF signal carried by the IF cable 305 in FIG. 5.

In an exemplary embodiment, the graph 630 shows the IF1 signal provided to the IFIC 360 over the IF cable 305. The IF signal is downconverted by the downconverter 367 using a third LO signal, LO3_I and LO3_Q provided by the fractional-N PLL 375.

In an exemplary embodiment, the graph 640 shows the downconverted first signal bandwidth 612 centered around DC.

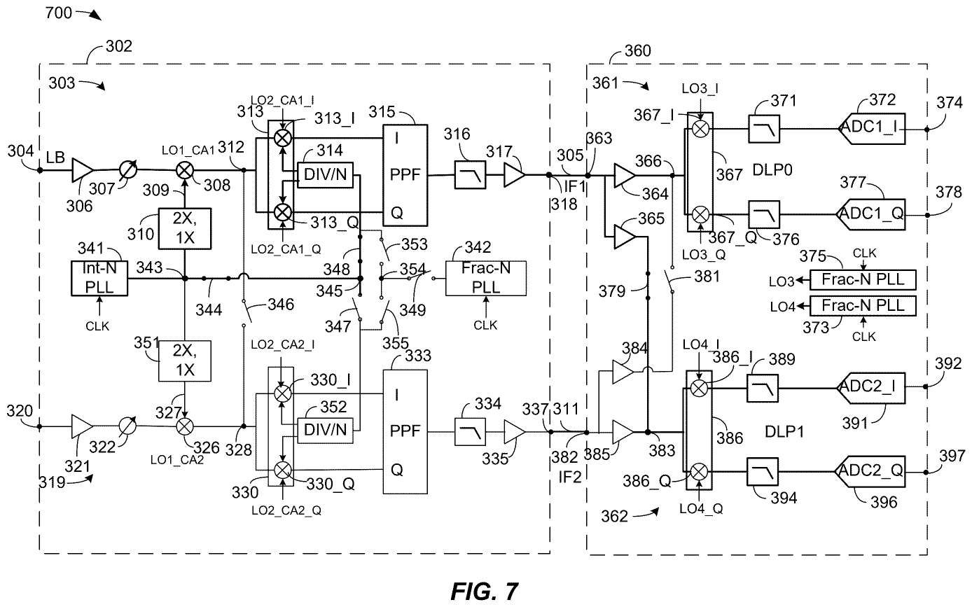

FIG. 7 is a block diagram 700 of a receive portion of a millimeter wave integrated circuit (mmW-IC) and an intermediate frequency integrated circuit (IFIC) in accordance with an exemplary embodiment of the disclosure. The configuration shown in FIG. 7 applies to an exemplary situation where a single band (LB in this example) having a bandwidth greater than the maximum bandwidth supported by the downlink path, is processed by the mmW-IC 302 and the IFIC 360 where the digital processing in the IFIC 360 is divided between the receive path 361 and the receive path 362 in an intra-band CA configuration.

In this example, the elements in the mmW-IC 302 and the IFIC 360 that process a LB signal received at the port 304 are shown in bold line. In this example, the LB signal is applied to the LNA 306 and the PS 307 and downconverted by the mixer 308 using a local oscillator (LO) signal LO1_CA1 LO provided by the integer-N PLL 341 and the multiplier 310. The downconverter 313 further downconverts the signal using an LO signal LO2_CA1 (LO2_CA1_I and LO2_CA1_Q) provided by the integer-N PLL 341 and the divider 314. The signal is then processed by the PPF 315, low pass filter 316 and IF VGA 317 and provided to the IFIC 360 over the IF cable 305.

The receive signal is then processed by the LNA 364 and by the LNA 365 and provided to the downconverter 367 and to the downconverter 386. The downconverter 367 receives an LO signal, LO3_I and LO3_Q from the fractional-N PLL 375 and the downconverter 386 receives an LO signal, LO4_I and LO4_Q from the fractional-N PLL 373. The downconverted in-phase and quadrature signals from the downconverter 367 are then provided to the low pass filters 371 and 376 and to the ADCs 372 and 377 for further processing. Similarly, the downconverted in-phase and quadrature signals from the downconverter 386 are then provided to the low pass filters 389 and 394 and to the ADCs 391 and 396 for further processing.

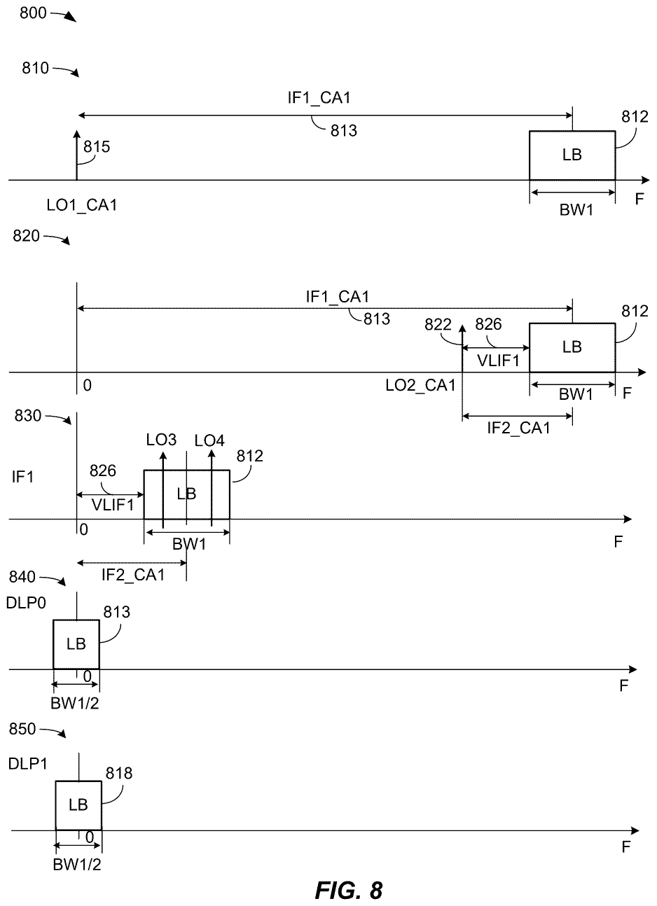

FIG. 8 is a graphical illustration 800 showing signal bandwidth and local oscillator (LO) signals for the single band (LB in this example) bandwidth smaller than the maximum bandwidth supported by the downlink path shown in FIG. 7. FIG. 8 includes a graph 810 having a horizontal axis showing frequency increasing to the right. An exemplary first signal band 812 is shown as having a bandwidth of “BW1” and an exemplary LO signal, LO1_CA1 is shown using reference numeral 815. The exemplary signal IF1_CA1 813 denotes the first IF signal provided by the mixer 308.

In an exemplary embodiment, the graph 820 shows the first signal band 812 and also shows an LO signal, LO2_CA1 822, provided to the downconverter 313 by the integer-N PLL 341 (FIG. 7) and the divider 314. The LO2_CA1 signal is located an offset of VLIF1 826 from the lower frequency of the first signal band 812. The distance from the center of the first signal band 812 to the LO2_CA1 LO signal is the second IF frequency, IF2_CA1, which is the VLIF signal carried by the IF cable 305 in FIG. 7.

In an exemplary embodiment, the graph 830 shows the IF1 signal provided to the IFIC 360 over the IF cable 305 and the IF cable 311. The IF signal is downconverted by the downconverter 367 using a third LO signal, LO3_I and LO3_Q provided by the fractional-N PLL 375; and is downconverted by the downconverter 386 using a fourth LO signal, LO4_I and LO4_Q provided by the fractional-N PLL 373. In an exemplary embodiment, the chosen frequency offset for VLIF1 and VLIF2 are independent of each other.

In an exemplary embodiment, LO3_I, LO3_Q frequencies are selected such that the graph 840 shows the downconverted first signal bandwidth 813 centered around DC; however, the resulting bandwidth in this example is BW1/2. Similarly, LO4_I, LO4_Q frequencies are selected such that the graph 850 shows the downconverted first signal bandwidth 818 centered around DC; however, the resulting bandwidth in this example is BW1/2. In this example, an equal BW split is shown for DLP0 (downlink path or downlink pipe 0) and DLP1. In an exemplary embodiment, DLP 0 refers to the processing performed by the receive path 361 and DLP1 refers to the processing performed by the receive path 362. Other implementations can select LO3, LO4 such that a desired BW split ratio can be implemented.

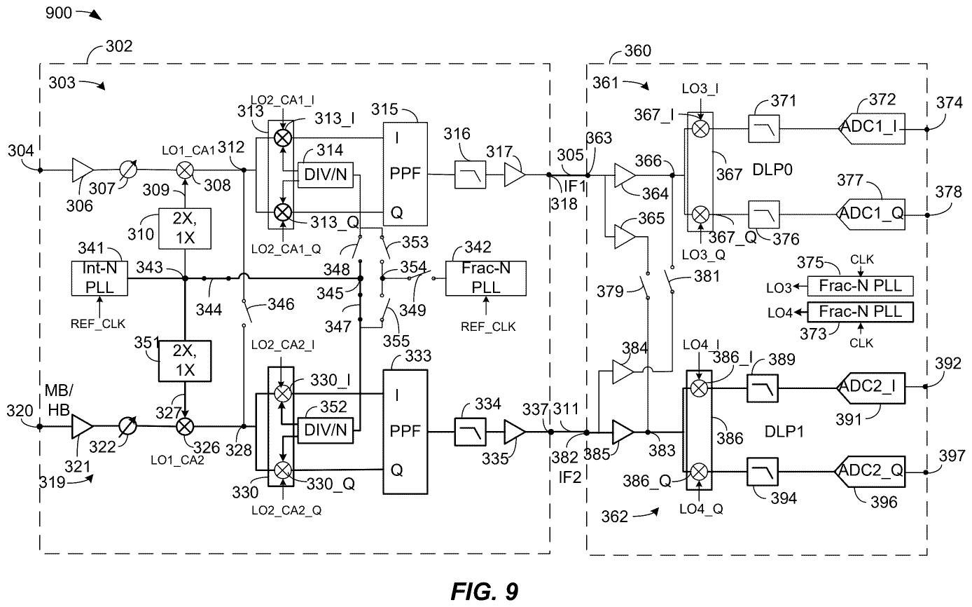

FIG. 9 is a block diagram 900 of a receive portion of a millimeter wave integrated circuit (mmW-IC) and an intermediate frequency integrated circuit (IFIC) in accordance with an exemplary embodiment of the disclosure. The configuration shown in FIG. 9 applies to an exemplary situation where a single band (MB/HB in this example) having a bandwidth smaller than the maximum signal path bandwidth of the receive path 319 and the receive path 362, is processed by the mmW-IC 302 and the IFIC 360. In this example, the elements in the mmW-IC 302 and the IFIC 360 that process a MB/HB signal received at the port 320 are shown in bold line. In this example, the MB/HB signal is applied to the LNA 321 and the PS 322 and downconverted by the mixer 326 using a local oscillator (LO) signal LO1_CA2 provided by the integer-N PLL 341 and the multiplier 351. The downconverter 330 further downconverts the signal using an LO signal LO2_CA2 (LO2_CA2_I and LO2_CA2_Q) provided by the integer-N PLL 341 and the divider 352. The signal is then processed by the PPF 333, low pass filter 334 and IF VGA 335 and provided to the IFIC 360 over the IF cable 311.

The receive signal is then processed by the LNA 385 and provided to the downconverter 386. The downconverter 386 receives an LO signal, LO4_I and LO4_Q from the fractional-N PLL 373. The downconverted in-phase and quadrature signals are then provided to the lowpass filters 389 and 394 and to the ADCs 391 and 396 for further processing.

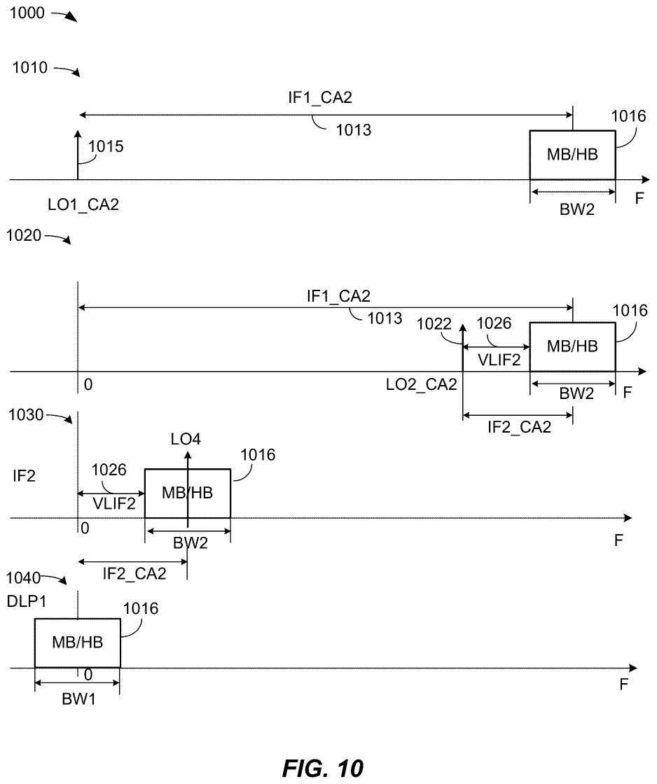

FIG. 10 is a graphical illustration 1000 showing signal bandwidth and local oscillator (LO) signals for the single band (MB/HB in this example) bandwidth smaller than 800 MHz shown in FIG. 9. FIG. 10 includes a graph 1010 having a horizontal axis showing frequency increasing to the right. An exemplary second signal band 1016 is shown as having a bandwidth of “BW2” and an exemplary LO signal, LO1_CA2 is shown using reference numeral 1015. The exemplary signal IF1_CA2 1013 denotes the first IF signal provided by the mixer 326.

In an exemplary embodiment, the graph 1020 shows the second signal band 1016 and also shows an LO signal, LO2_CA2 1022, provided to the downconverter 330 by the integer-N PLL 341 (FIG. 9). The LO2_CA2 LO signal is located an offset of VLIF2 1026 from the lower frequency of the second signal band 1016. The distance from the center of the second signal band 1016 to the LO2_CA2 LO signal is the second IF frequency, IF2_CA2, which is the VLIF signal carried by the IF cable 311 in FIG. 9.

In an exemplary embodiment, the graph 1030 shows the IF2 signal provided to the IFIC 360 over the IF cable 311. The IF signal is downconverted by the downconverter 386 using a fourth LO signal, LO4_I and LO4_Q provided by the fractional-N PLL 373.

In an exemplary embodiment, the graph 1040 shows the downconverted second signal bandwidth 1016 centered around DC.

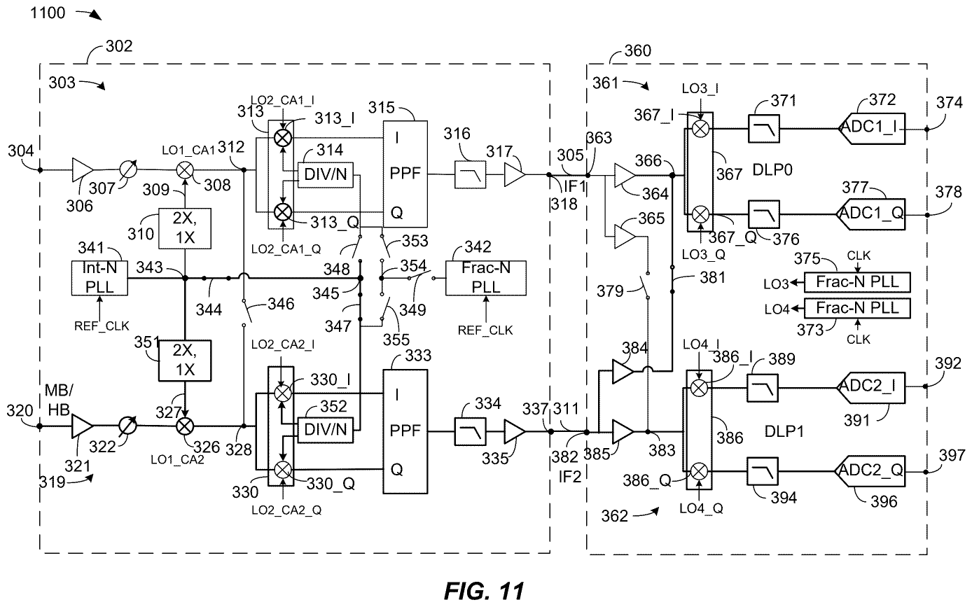

FIG. 11 is a block diagram 1100 of a receive portion of a millimeter wave integrated circuit (mmW-IC) and an intermediate frequency integrated circuit (IFIC) in accordance with an exemplary embodiment of the disclosure. The configuration shown in FIG. 11 applies to an exemplary situation where a single band (MB/HB in this example) having a bandwidth smaller than the maximum signal path bandwidth for the receive path 319 is processed by the mmW-IC 302 and the IFIC 360 where the digital processing in the IFIC 360 is divided between the receive path 361 and the receive path 362 in an intra-band CA configuration.

. In this example, the elements in the mmW-IC 302 and the IFIC 360 that process a MB/HB signal received at the port 320 are shown in bold line. In this example, the MB/HB signal is applied to the LNA 321 and the PS 322 and downconverted by the mixer 326 using a local oscillator (LO) signal LO1_CA2 provided by the integer-N PLL 341 and multiplier 351. The downconverter 330 further downconverts the signal using an LO signal LO2_CA2 (LO2_CA2_I and LO2_CA2_Q) provided by the integer-N PLL 341 and the divider 352. The signal is then processed by the PPF 333, low pass filter 334 and IF VGA 335 and provided to the IFIC 360 over the IF cable 311.

The receive signal is then processed by the LNA 385 and by the LNA 384 and provided to the downconverter 386 and to the downconverter 367. The downconverter 367 receives an LO signal, LO3_I and LO3_Q from the fractional-N PLL 375 and the downconverter 386 receives an LO signal, LO4_I and LO4_Q from the fractional-N PLL 373. The downconverted in-phase and quadrature signals from the downconverter 367 are then provided to the lowpass filters 371 and 376 and to the ADCs 372 and 377 for further processing. Similarly, the downconverted in-phase and quadrature signals from the downconverter 386 are then provided to the lowpass filters 389 and 394 and to the ADCs 391 and 396 for further processing.

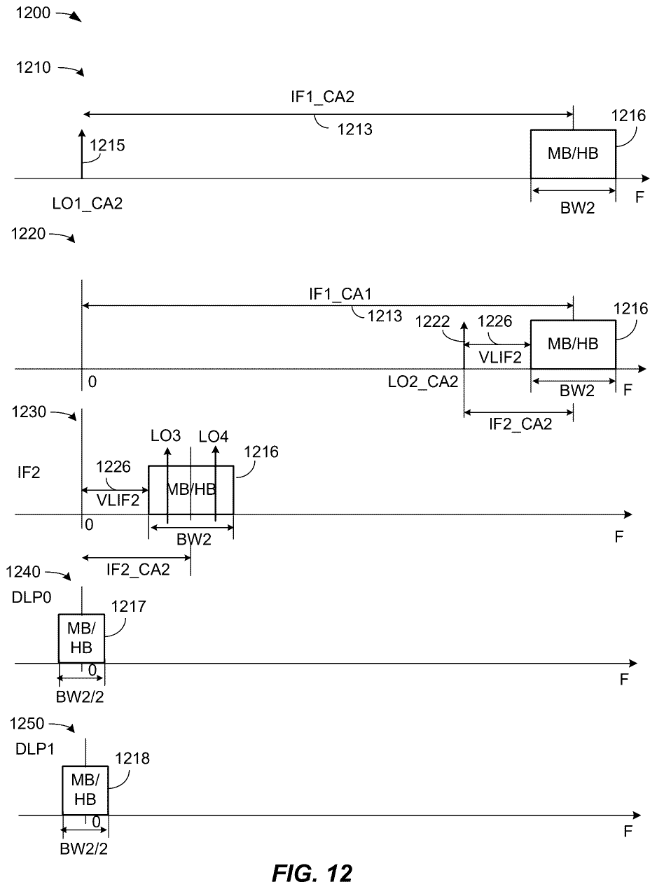

FIG. 12 is a graphical illustration 1200 showing signal bandwidth and local oscillator (LO) signals for the single band (MB/HB in this example) bandwidth smaller than the maximum bandwidth of the signal path 319 shown in FIG. 11. FIG. 12 includes a graph 1210 having a horizontal axis showing frequency increasing to the right. An exemplary second signal band 1216 is shown as having a bandwidth of “BW2” and an exemplary LO signal, LO1_CA2 is shown using reference numeral 1215. The exemplary signal IF1_CA2 1213 denotes the first IF signal provided by the mixer 326.

In an exemplary embodiment, the graph 1220 shows the second signal band 1216 and also shows an LO signal, LO2_CA2 1222, provided to the downconverter 330 by the integer-N PLL 341 (FIG. 11) and the divider 352. The LO2_CA2 signal is located an offset of VLIF2 1226 from the lower frequency of the second signal band 1216. The distance from the center of the second signal band 1216 to the LO2_CA2 LO signal 1222 is the second IF frequency, IF2_CA2, which is the VLIF signal carried by the IF cable 311 in FIG. 11.

In an exemplary embodiment, the graph 1230 shows the IF2 signal provided to the IFIC 360 over the IF cable 311. The IF signal is downconverted by the downconverter 367 using a third LO signal, LO3_I and LO3_Q provided by the fractional-N PLL 375; and is downconverted by the downconverter 386 using a fourth LO signal, LO4_I and LO4_Q provided by the fractional-N PLL 373.

In an exemplary embodiment, LO3_I, LO3_Q frequencies are selected such that the graph 1240 shows the downconverted second signal bandwidth 1217 centered around DC; however, the resulting bandwidth in this example is BW2/2. Similarly, LO4_I, LO4_Q frequencies are selected such that the graph 1250 shows the downconverted second signal bandwidth 1218 centered around DC; however, the resulting bandwidth in this example is BW2/2. In this example, an equal BW split is shown for DLP0 and DLP1. Other implementations can select LO3, LO4 such that a desired BW split ratio can be implemented.

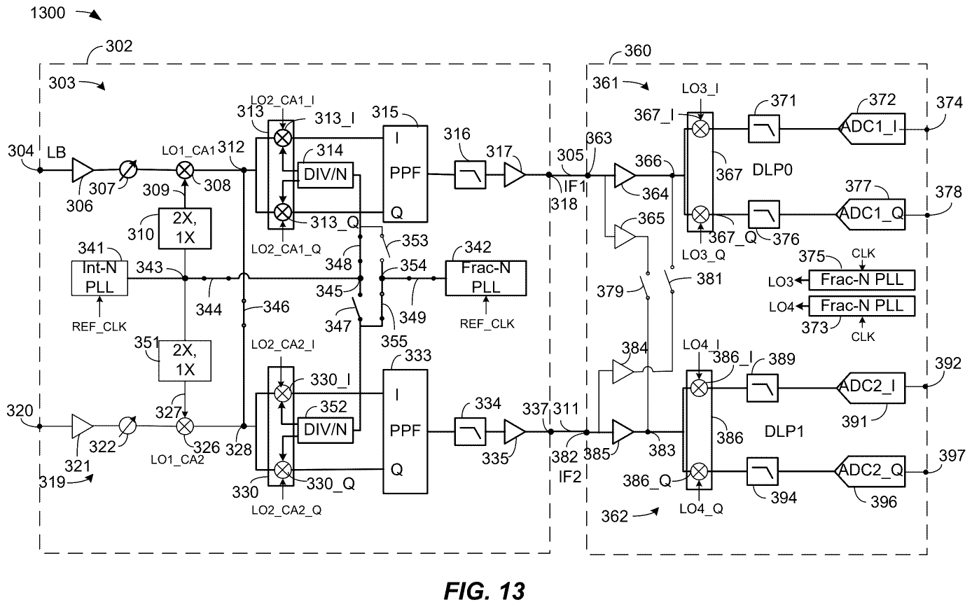

FIG. 13 is a block diagram 1300 of a receive portion of a millimeter wave integrated circuit (mmW-IC) and an intermediate frequency integrated circuit (IFIC) in accordance with an exemplary embodiment of the disclosure. The configuration shown in FIG. 13 applies to an exemplary situation where a single band (LB in this example) having a bandwidth greater than the maximum signal path bandwidth, is processed by the mmW-IC 302 and the IFIC 360. In this example, the elements in the mmW-IC 302 and the IFIC 360 that process a LB signal received at the port 304 are shown in bold line. In this example, the LB signal is applied to the LNA 306 and the PS 307 and downconverted by the mixer 308 using a local oscillator (LO) signal LO1_CA1 provided by the integer-N PLL 341 and the multiplier 310. In this exemplary embodiment, the output of the mixer 308 is provided to the downconverter 313 and to the downconverter 330 via the conductive switch 346.

The downconverter 313 further downconverts the signal using an LO signal LO2_CA1 (LO2_CA1_I and LO2_CA1_Q) provided by the integer-N PLL 341 and the divider 314. The signal is then processed by the PPF 315, low pass filter 316 and IF VGA 317 and provided to the IFIC 360 over the IF cable 305. Similarly, the downconverter 330 further downconverts the signal using an LO signal LO2_CA2 (LO2_CA2_I and LO2_CA2_Q) provided by the fractional-N PLL 342 and the divider 352. The signal is then processed by the PPF 333, low pass filter 334 and IF VGA 335 and provided to the IFIC 360 over the IF cable 311. In this manner, the mmW-IC 302 can operate on two different frequency signals simultaneously.

The receive signal is then processed by the LNA 364 and provided to the downconverter 367. The downconverter 367 receives an LO signal, LO3_I and LO3_Q from the fractional-N PLL 375. The downconverted in-phase and quadrature signals are then provided to the lowpass filters 371 and 376 and to the ADCs 372 and 377 for further processing. Similarly, the receive signal is then processed by the LNA 385 and provided to the downconverter 386. The downconverter 3686 receives an LO signal, LO4_I and LO4_Q from the fractional-N PLL 373. The downconverted in-phase and quadrature signals are then provided to the bandpass filters 389 and 394 and to the ADCs 391 and 396 for further processing.

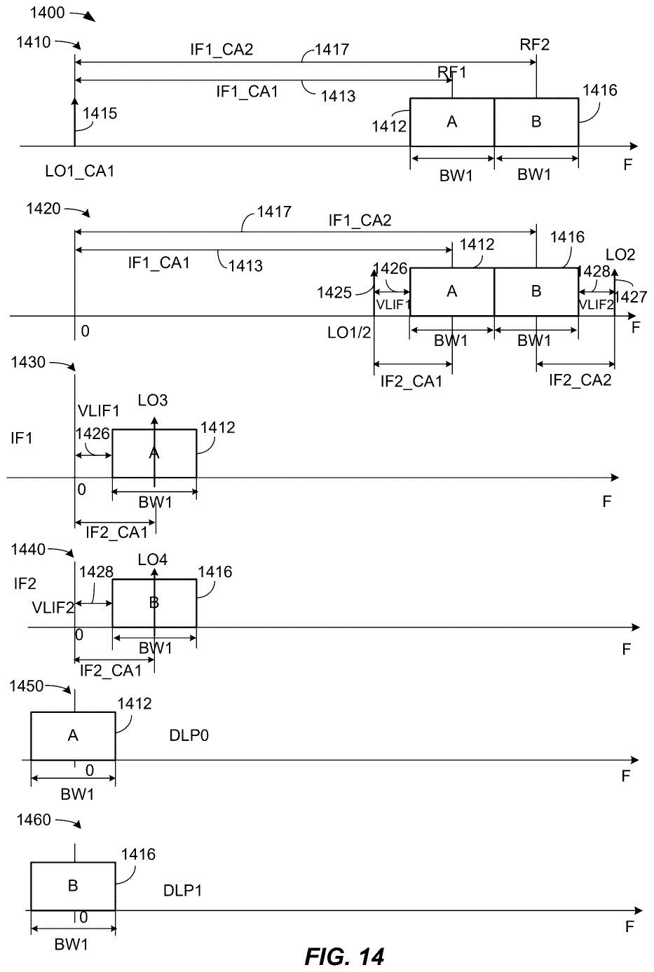

FIG. 14 is a graphical illustration 1400 showing signal bandwidth and local oscillator (LO) signals for the single band LB in this example) bandwidth greater than the maximum bandwidth of the signal path 303 shown in FIG. 13. FIG. 14 includes a graph 1410 having a horizontal axis showing frequency increasing to the right. Exemplary first frequency portion 1412 and second frequency portion 1416 are shown as each having a bandwidth of “BW1”. Although both the first frequency portion 1412 and second frequency portion 1416 are shown as each having a bandwidth of BW1, both first frequency portion 1412 and second frequency portion 1416 are separate portions, or chunks, of the same frequency band. For example, the total bandwidth may be 1600 MHz and each of the frequency portions 1412 and 1416 may be 800 MHz. An exemplary LO signal, LO1_CA1 is shown using reference numeral 1415. The exemplary signal IF1_CA1 1413 denotes a first IF signal provided by the mixer 308 corresponding to a first RF signal RF1 (first frequency portion 1412), and the exemplary signal IF1_CA2 1417 denotes a second IF signal provided by the mixer 308 corresponding to a second RF signal RF2 (second frequency portion 1416).

In an exemplary embodiment, the graph 1420 shows the first frequency portion 1412 and the second frequency portion 1416. The graph 1420 also shows an LO signal, LO1/2 (LO1 divided by 2) 1425 provided to the downconverter 313 by the integer-N PLL 341 (FIG. 13) and the divider 314. The graph 1420 also shows an LO signal, LO2 1427 provided to the downconverter 330 by the fractional-N PLL 342 (FIG. 13) and the divider 352. The LO1/2 signal is located an offset of VLIF1 1426 from the lower frequency of the first frequency portion 1412. The distance from the center of the first frequency portion 1412 to the LO1/2 signal 1425 is the second IF frequency, IF2_CA1, which is the VLIF signal carried by the IF cable 305 in FIG. 13. The LO2 signal is located an offset of VLIF2 1428 from the upper frequency of the second frequency portion 1416. The distance from the center of the second frequency portion 1416 to the LO2 signal is the second IF frequency, IF2_CA2, which is the VLIF signal carried by the IF cable 311 in FIG. 13. If VLIF1 and VLIF2 frequency offsets are the same value, then a single fractional-N PLL 375 (for example, LO3) can be used in the IFIC 360 instead of two fractional-N PLLs for LO3/LO4. Further, in this example, LO2=LO1/N (where N=2 in this example) for downconverting one bandwidth segment (first frequency portion (A) 1412) of signal whereas the fractional-N PLL 375 may be used to downconvert the other bandwidth segment (second frequency portion (B) 1416 in the IFIC 360).

In an exemplary embodiment, the graph 1430 shows the IF1 signal (first frequency portion 1412) provided to the IFIC 360. The IF1 signal is downconverted by the downconverter 367 using a third LO signal, LO3_I and LO3_Q provided by the fractional-N PLL 375.

In an exemplary embodiment, the graph 1440 shows the IF2 signal (second frequency portion 1416) provided to the IFIC 360. Assuming that the VLIF2 offset is different from the VLIF1 offset, the IF2 signal is downconverted by the downconverter 386 using a fourth LO signal, LO4_I and LO4_Q provided by the fractional-N PLL 373.

In an exemplary embodiment, LO3_I and LO3_Q frequencies are selected such that the downconverted first frequency portion 1412 is centered around DC as shown in the graph 1450. Similarly, LO4_I and LO4_Q frequencies are selected such that the downconverted second frequency portion 1416 is centered around DC as shown in the graph 1460.

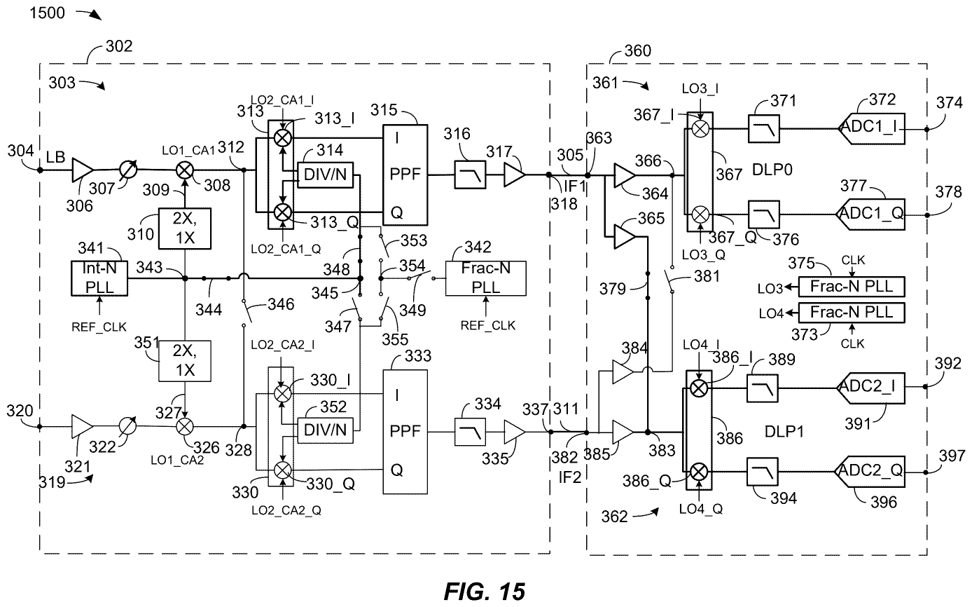

FIG. 15 is a block diagram 1500 of a receive portion of a millimeter wave integrated circuit (mmW-IC) and an intermediate frequency integrated circuit (IFIC) in accordance with an exemplary embodiment of the disclosure for an intra-band CA configuration. The configuration shown in FIG. 15 applies to an exemplary situation where a single band (LB in this example) is processed by the mmW-IC 302 and the IFIC 360 where the digital processing in the IFIC 360 is divided between the receive path 361 and the receive path 362.

In this example, the elements in the mmW-IC 302 and the IFIC 360 that process a LB signal received at the port 304 are shown in bold line. In this example, the LB signal is applied to the LNA 306 and the PS 307 and downconverted by the mixer 308 using a local oscillator (LO) signal LO1_CA1 LO provided by the integer-N PLL 341 and multiplier 310. The downconverter 313 further downconverts the signal using an LO signal LO2_CA1 (LO2_CA1_I and LO2_CA1_Q) provided by the integer-N PLL 341 and the divider 314. The signal is then processed by the PPF 315, low pass filter 316 and IF VGA 317 and provided to the IFIC 360 over the IF cable 305.

The receive signal is then processed by the LNA 364 and by the LNA 365 and provided to the downconverter 367 and to the downconverter 386. The downconverter 367 receives an LO signal, LO3_I and LO3_Q from the fractional-N PLL 375 and the downconverter 386 receives an LO signal, LO4_I and LO4_Q from the fractional-N PLL 373. The downconverted in-phase and quadrature signals from the downconverter 367 are then provided to the lowpass filters 371 and 376 and to the ADCs 372 and 377 for further processing. Similarly, the downconverted in-phase and quadrature signals from the downconverter 386 are then provided to the lowpass filters 389 and 394 and to the ADCs 391 and 396 for further processing.

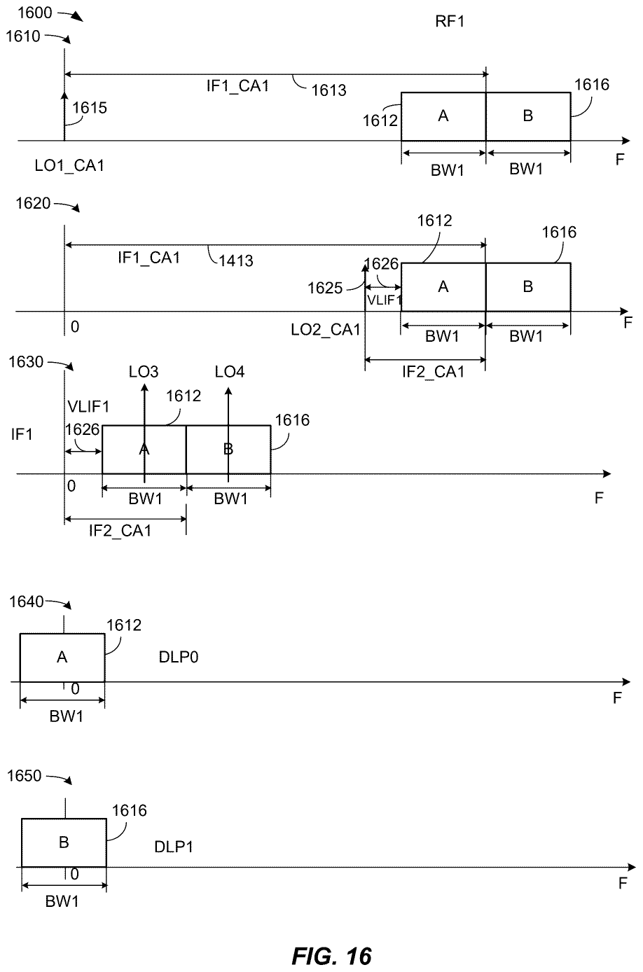

FIG. 16 is a graphical illustration 1600 showing signal bandwidth and local oscillator (LO) signals for the single band LB (in this example) bandwidth greater than the maximum bandwidth of the receive path 361 in the IFIC shown in FIG. 15. FIG. 16 includes a graph 1610 having a horizontal axis showing frequency increasing to the right. Exemplary first frequency portion 1612 and second frequency portion 1616 are shown as each having a bandwidth of “BW1” and an exemplary LO signal, LO1_CA1 is shown using reference numeral 1615. The exemplary signal IF1_CA1 1613 denotes a first IF signal provided by the mixer 308 corresponding to a first RF signal.

In an exemplary embodiment, the graph 1620 shows the first frequency portion 1612 and the second frequency portion 1616. The graph 1620 also shows an LO signal, LO2_CA1 1625 provided to the downconverter 313 by the integer-N PLL 341 (FIG. 15) and the divider 314. The LO2_CA1 signal 1625 is located an offset of VLIF1 1626 from the lower frequency of the first frequency portion 1612. The distance from the upper frequency of the first frequency portion 1612 to the LO2_CA1 signal is the second IF frequency, IF2_CA1, which is the VLIF signal carried by the IF cable 305 in FIG. 15.

In an exemplary embodiment, the graph 1630 shows the IF1 signal (on the IF cable 305 in FIG. 15) provided to the IFIC 360. The IF1 signal comprises the signals in the first frequency portion 1612 and the second frequency portion 1616. The first frequency portion 1612 is downconverted to DC by the downconverter 367 using a third LO signal, LO3_I and LO3_Q provided by the fractional-N PLL 375. The second frequency portion 1616 is downconverted to DC by the downconverter 386 also using the fourth LO signal, LO4_I and LO4_Q provided by the fractional-N PLL 373.

In an exemplary embodiment, the graph 1640 shows the downconverted first frequency portion 1612 centered around DC. Similarly, the graph 1650 shows the downconverted second frequency portion 1616 centered around DC.

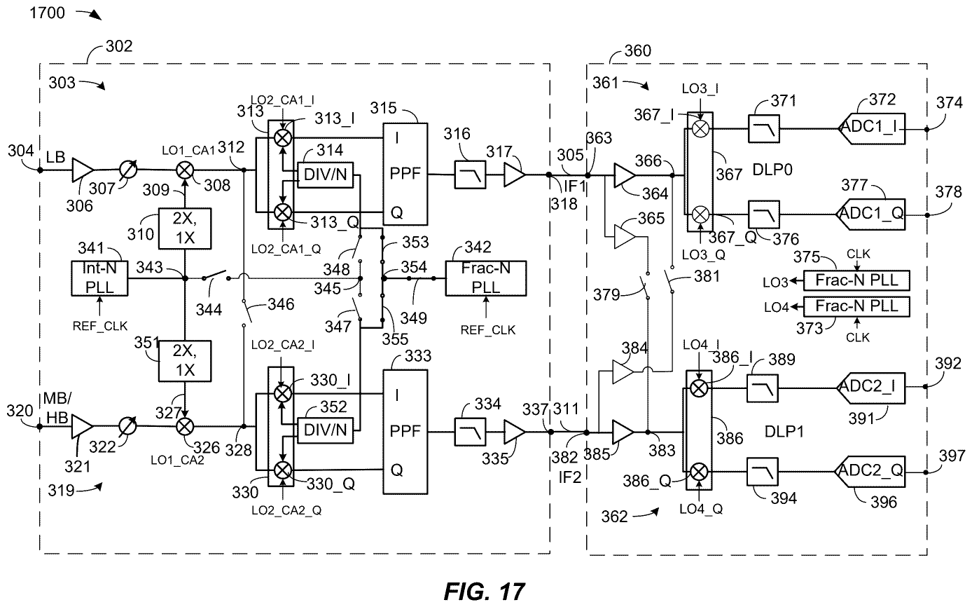

FIG. 17 is a block diagram 1700 of a receive portion of a millimeter wave integrated circuit (mmW-IC) and an intermediate frequency integrated circuit (IFIC) in accordance with an exemplary embodiment of the disclosure. The configuration shown in FIG. 17 applies to an exemplary situation where an inter-band carrier aggregation (CA) (LB+MB in this example) signal having a bandwidth smaller than the maximum bandwidth of the receive paths 303 and 319 is processed by the mmW-IC 302 and the IFIC 360. In this example, the elements in the mmW-IC 302 and the IFIC 360 that process a LB signal received at the port 304 and that process a MB signal at the port 320 are shown in bold line.

In this example, the LB signal is applied to the LNA 306 and the PS 307 and downconverted by the mixer 308 using a local oscillator (LO) signal LO1_CA1 provided by the integer-N PLL 341 and the multiplier 310. The downconverter 313 further downconverts the signal using an LO signal LO2_CA1 (LO2_CA1_I and LO2_CA1_Q) provided by the fractional-N PLL 342 and the divider 314. The signal is then processed by the PPF 315, low pass filter 316 and IF VGA 317 and provided to the IFIC 360 over the IF cable 305.

The LB receive signal is then processed by the LNA 364 and provided to the downconverter 367. The downconverter 367 receives an LO signal, LO3_I and LO3_Q from the fractional-N PLL 375. The downconverted in-phase and quadrature signals are then provided to the lowpass filters 371 and 376 and to the ADCs 372 and 377 for further processing.

In this example, the MB (MB/HB) signal is applied to the LNA 321 and the PS 322 and downconverted by the mixer 326 using a local oscillator (LO) signal LO1_CA2 provided by the integer-N PLL 341 and the multiplier 351. The downconverter 330 further downconverts the signal using an LO signal LO2_CA2 (LO2_CA2_I and LO2_CA2_Q) provided by the fractional-N PLL 342 and the divider 352. The signal is then processed by the PPF 333, low pass filter 334 and IF VGA 335 and provided to the IFIC 360 over the IF cable 311.

The MB receive signal is then processed by the LNA 385 and provided to the downconverter 386. The downconverter 386 receives an LO signal, LO4_I and LO4_Q from the fractional-N PLL 373. The downconverted in-phase and quadrature signals are then provided to the lowpass filters 389 and 394 and to the ADCs 391 and 396 for further processing.

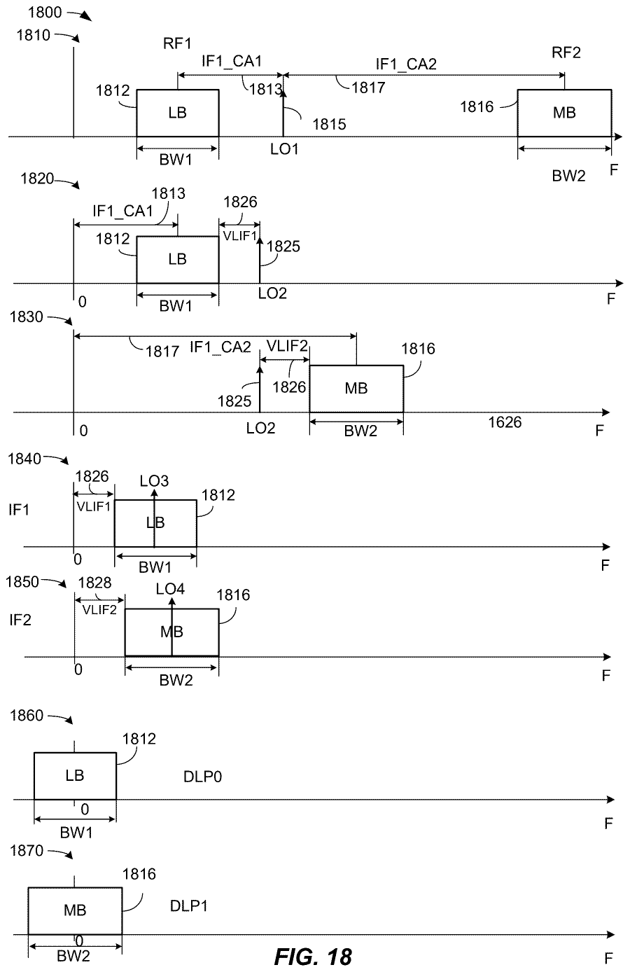

FIG. 18 is a graphical illustration 1800 showing signal bandwidth and local oscillator (LO) signals for the inter-band carrier aggregation (CA) (LB+MB in this example) signal having a bandwidth smaller than the maximum signal path bandwidth of the receive paths 303 and 319 shown in FIG. 17. FIG. 18 includes a graph 1810 having a horizontal axis showing frequency increasing to the right. An exemplary first signal band 1812 (LB) is shown as having a bandwidth “BW1” nd an exemplary second signal band 1816 (MB) is shown as having a bandwidth of “BW2”. In an exemplary embodiment, the first signal band 1812 may correspond to a first RF frequency, RF1; and the second signal band 1816 may correspond to a second RF frequency, RF2. An exemplary LO signal, LO1 is shown using reference numeral 1815. In an exemplary embodiment, a common LO1 signal to downconvert both signal bands 1812 and 1816 can be chosen such that:

LO1=(RF₁+RF₂)/2−(BW₁+BW₂)/4−(VLIF₁+VLIF₂)/2.

The exemplary signal IF1_CA1 1813 denotes a first IF signal provided by the mixer 308 corresponding to the first signal band 1812 (RF1) and an exemplary signal IF1_CA2 1817 denotes a second IF signal provided by the mixer 326 corresponding to the second signal band 1816 (RF2).

In an exemplary embodiment, the graph 1820 shows a second common LO signal to downconvert both signal bands 1812 and 1816, LO2 1825 provided to the downconverter 313 by the fractional-N PLL 342 and the divider 314. The LO2 signal 1825 is located an offset of VLIF1 1826 from the upper frequency of the first signal band 1812. The center of the first signal band 1812 is located at the IF frequency, IF1_CA1 1813 and is provided to the IFIC 360 over the IF cable 305.

In an exemplary embodiment, the graph 1830 shows the second LO signal, LO2 1825 provided to the downconverter 330 by the fractional-N PLL 342 and the divider 352. In an exemplary embodiment, LO2 can be chosen such that:

LO2=(RF₂−RF₁)/2+(BW₁−BW₂)/4+(VLIF₁−VLIF₂)/2.

The LO2 signal 1825 is located an offset of VLIF2 1826 from the lower frequency of the second signal band 1816. The center of the second signal band 1816 is located at an IF frequency, IF1_CA2 1817 and is provided to the IFIC 360 over the IF cable 311.

In an exemplary embodiment, the graph 1840 shows the IF1 signal (on the IF cable 305 in FIG. 17) provided to the IFIC 360. The IF1 signal comprises the signal in the first signal band 1812. The first signal band 1812 is downconverted by the downconverter 367 using a third LO signal, LO3_I and LO3_Q provided by the fractional-N PLL 375.

In an exemplary embodiment, the graph 1850 shows the IF2 signal (on the IF cable 311 in FIG. 17) provided to the IFIC 360. The IF2 signal comprises the signal in the second signal band 1816. The second signal band 1816 is downconverted by the downconverter 386 using a fourth LO signal, LO4_I and LO4_Q provided by the fractional-N PLL 373.

In an exemplary embodiment, the graph 1860 shows the downconverted first signal band 1812 centered around DC. Similarly, the graph 1870 shows the downconverted second signal band 1816 centered around DC.

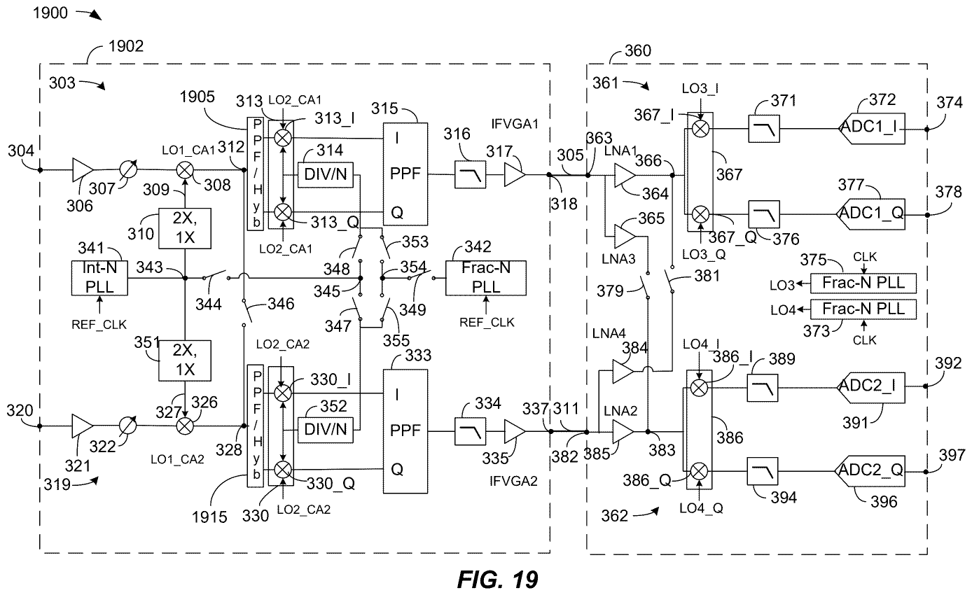

FIG. 19 is a block diagram 1900 of a receive portion of a millimeter wave integrated circuit (mmW-IC) and an intermediate frequency integrated circuit (IFIC) in accordance with an alternative exemplary embodiment of the disclosure. The circuit shown in FIG. 19 is similar to the circuit shown in FIG. 5. However, the mmW IC 1902 includes a PPF/Hybrid circuit 1905 located between the mixer 308 and the downconverter 313, and includes a PPF/Hybrid circuit 1915 located between the mixer 326 and the downconverter 330.

Generating I and Q LO signals consumes considerable power, particularly at the second IF frequency. Generating I and Q signals in the signal path can enable the use of real LO circuitry. This can be achieved by using a polyphase filter or a hybrid before the downconverter 313 and 330 as shown in FIG. 19. The polyphase filter 1905 before the downconverter 313 and the polyphase filter 1915 before the downconverter 330 can be designed to generate I and Q signal in the signal paths 303 and 319, respectively, to have good quadrature balance for jammer rejection in the image band. This eliminates the generation of I and Q signals in the LO path, which consumes significant power and has a lot of complexity to achieve I/Q balance with low loss. In this exemplary embodiment, the divider 314 and the divider 352 provide a single LO phase (LO_I) to each of the I and Q mixers in the downconverter 313 and in the downconverter 330.

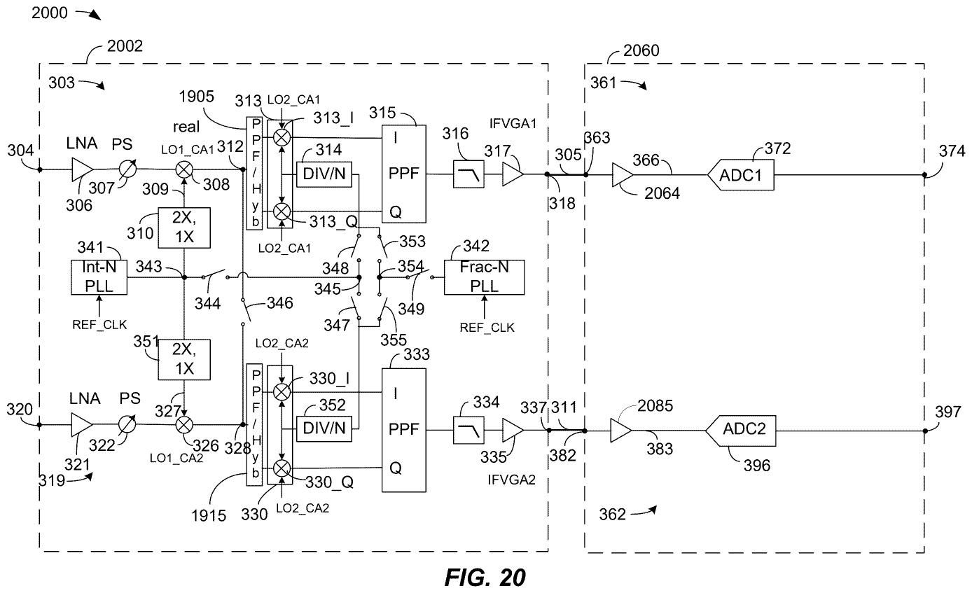

FIG. 20 is a block diagram 2000 of a receive portion of a millimeter wave integrated circuit (mmW-IC) and an intermediate frequency integrated circuit (IFIC) in accordance with an alternative exemplary embodiment of the disclosure. The circuit shown in FIG. 20 is similar to the circuit shown in FIG. 19. However, in FIG. 20, the IFIC 2060 includes a single-ended to differential (S2D) buffer 2064 connected to the IF cable 305 at the port 363 and an S2D buffer 2085 connected to the IF cable 311 at the port 382. The S2D buffer 2064 is connected to the ADC 372 and the S2D buffer 2085 is connected to the ADC 396. This arrangement still alleviates the drawbacks of using a complex BPF in the mmW IC 2002 as well as the use of power consuming quadrature LO generation for the downconverter 313 and 330. A real LPF requires a bit higher order than complex to filter jammers and achieve anti-aliasing. It can be achieved with TIA+Rauch filter or TIA+Rauch filter+Rauch filter in a small area. This arrangement uses two PLLs in the mmW IC (integer-N PLL 341 and fractional-N PLL 342) to meet the desired IPN (integrated phase noise) specification. In this exemplary embodiment, the ADC 372 and the ADC 396 are real ADCs with sampling frequency sufficiently high to process the downconverted VLIF signal.

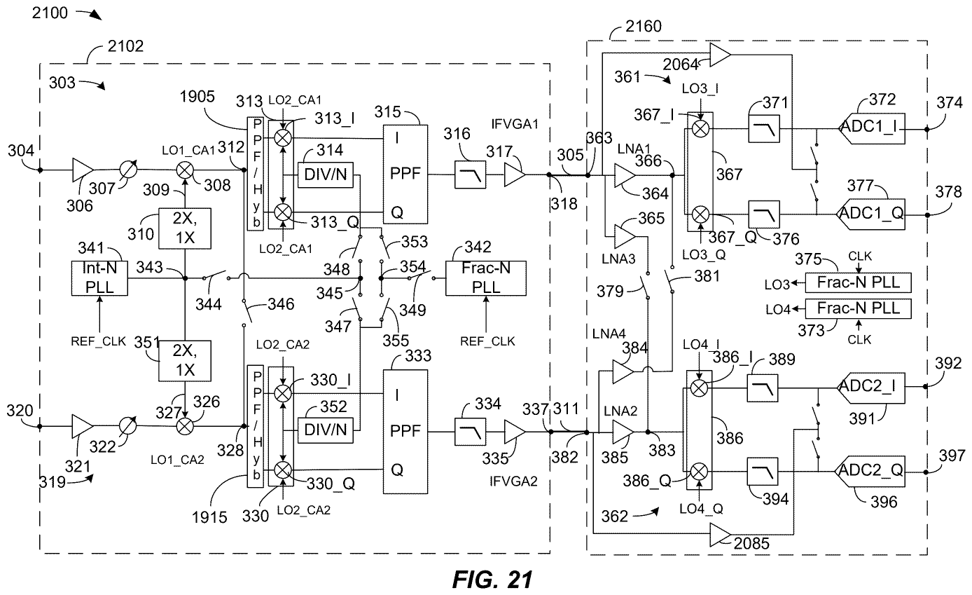

FIG. 21 is a block diagram 2100 of a receive portion of a millimeter wave integrated circuit (mmW-IC) and an intermediate frequency integrated circuit (IFIC) in accordance with an alternative exemplary embodiment of the disclosure. The circuit shown in FIG. 21 is a combination of the IFIC 360 in FIG. 19 and IFIC 2060 in FIG. 20. However, in FIG. 21, the IFIC 2160 includes a single-ended to differential (S2D) buffer 2064 connected to the IF cable 305 at the port 363 and an S2D buffer 2085 connected to the IF cable 311 at the port 382. The S2D buffer 2064 is switchably connected to the ADC 372 and the ADC 377. The S2D buffer 2085 is switchably connected to the ADC 391 and the ADC 396. Current in the IFIC 2160 can be saved by using the path formed by the S2D buffer and real ADC for low bandwidth low power modes (100 MHz/200 MHz) whereas receive paths 361 and 362 is used for high bandwidth, high power modes. The LNA, mixer, and real LPF path can be used for wide bandwidth modes, without overburdening the ADC sampling rates.

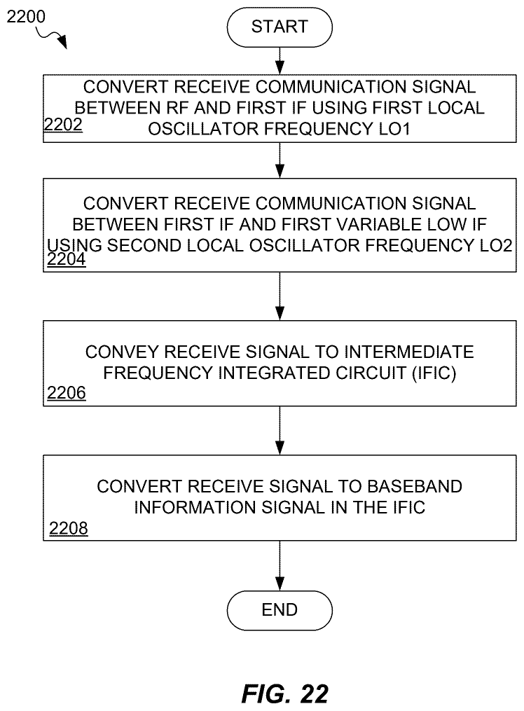

FIG. 22 is a flow chart 2200 describing an example of the operation of a method for signal conversion. The blocks in the method 2200 can be performed in or out of the order shown, and in some embodiments, can be performed at least in part in parallel.

In block 2202, a receive communication signal is converted between RF and a first IF. For example, a mixer 308 may receive a RF communication signal and convert the RF signal to a first IF signal.

In block 2204, the receive communication signal is converted between the first IF and a first variable low IF. For example, the downconverter 330 may convert the receive communication signal from the first IF to a first variable low IF signal.

In block 2206, a receive signal is conveyed to an intermediate frequency integrated circuit (IFIC). For example, a receive signal may be conveyed by the IF cable 305 from the mmW-IC 302 to the IFIC 360.

In block 2208, a receive signal is downconverted from a variable low intermediate frequency to baseband in the IFIC. For example, the downconverter 367 downconverts the variable low IF signal received from the mmW-IC 302 to a baseband information signal.

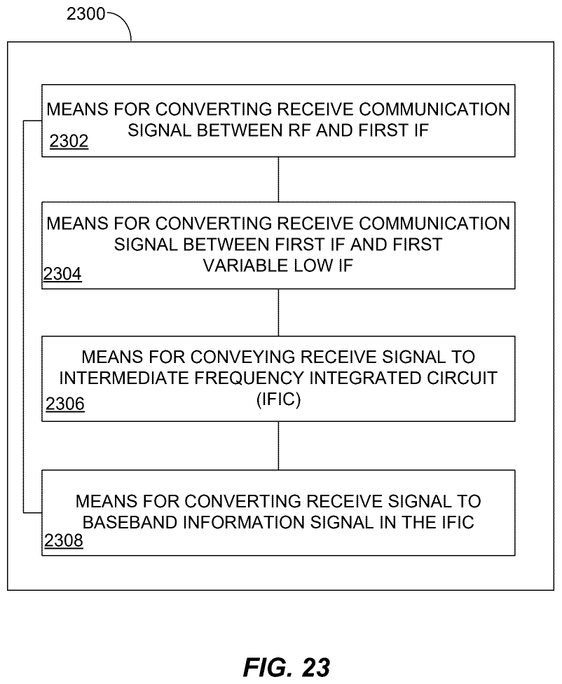

FIG. 23 is a functional block diagram of an apparatus 2300 for signal conversion. The apparatus 2300 comprises means 2302 for converting a receive communication signal between RF and a first IF. In certain embodiments, the means 2302 for converting a receive communication signal between RF and a first IF can be configured to perform one or more of the functions described in operation block 2202 of method 2200 (FIG. 22). In an exemplary embodiment, the means 2302 for converting a receive communication signal between RF and a first IF may comprise the mixer 308 configured to receive an RF communication signal and convert the RF communication signal to a first IF signal.

The apparatus 2300 may also comprise means 2304 for converting the receive communication signal between the first IF and a first variable low IF. In certain embodiments, the means 2304 for converting the receive communication signal between the first IF and a first variable low IF can be configured to perform one or more of the functions described in operation block 2204 of method 2200 (FIG. 22). In an exemplary embodiment, the means 2304 for converting the receive communication signal between the first IF and a first variable low IF may comprise the downconverter 313 configured to convert the receive communication signal from the first IF to a first variable low IF signal.

The apparatus 2300 may also comprise means 2306 for conveying a receive signal to an intermediate frequency integrated circuit (IFIC). In certain embodiments, the means 2306 for conveying a receive signal to an intermediate frequency integrated circuit (IFIC) can be configured to perform one or more of the functions described in operation block 2206 of method 2200 (FIG. 22). In an exemplary embodiment, the means 2306 for conveying a receive signal to an intermediate frequency integrated circuit (IFIC) may comprise the IF cable 305 configure to convey a receive signal from the mmW-IC 302 to the IFIC 360.

The apparatus 2300 may also comprise means 2308 for downconverting a receive signal from a variable low intermediate frequency to baseband in the IFIC. In certain embodiments, the means 2308 for downconverting a receive signal from a variable low intermediate frequency to baseband in the IFIC can be configured to perform one or more of the functions described in operation block 2208 of method 2200 (FIG. 22). In an exemplary embodiment, the means 2308 for downconverting a receive signal from a variable low intermediate frequency to baseband in the IFIC may comprise the downconverter 367 configured to downconvert the variable low IF signal received from the mmW-IC 302 to a baseband information signal. Examples means are included herein for ease of description. It will be understood that the means in FIG. 23 may comprise other components or similar components configured differently.

Implementation examples are described in the following numbered clauses:

1. A variable low intermediate frequency (VLIF), millimeter wave (mmW) communication system, comprising a receive section having a receive radio frequency (RF) conversion stage, the receive RF conversion stage configured to convert a receive communication signal between RF and a first receive IF using a first local oscillator (LO1) signal generated by an integer-N phase locked loop (PLL) circuit; a receive variable intermediate frequency (IF) conversion stage, the receive variable IF conversion stage configured to convert the first receive IF signal to a first receive variable low IF (VLIF) signal using a second local oscillator (LO2) signal generated by one of the integer-N PLL circuit or a fractional-N phase locked loop (PLL) circuit; and a third conversion stage configured to convert the first receive variable low IF (VLIF) signal to a near-baseband signal using a third local oscillator (LO3) signal generated by a second fractional-N PLL circuit.

2. The communication system of clause 1, wherein a single band signal having a bandwidth less than a maximum signal path bandwidth is downconverted using the first LO1 signal and the second LO2 signal and conveyed to the third conversion stage over one of two intermediate frequency (IF) cables.

3. The communication system of clause 1, wherein a single band signal having a bandwidth greater than a maximum signal path bandwidth is downconverted using the first LO1 signal and the second LO2 signal and conveyed to the third conversion stage over two intermediate frequency (IF) cables.

4. The communication system of any of clauses 1 through 3, wherein an inter-band carrier aggregation (CA) band signal is downconverted using the first LO1 signal and the second LO2 signal and conveyed to the third conversion stage over two intermediate frequency (IF) cables.

5. The communication system of any of clauses 1 through 4, wherein multiple receive paths for performing the RF conversion stage and the variable IF conversion stage use a common LO1 signal and a common LO2 signal.

6. The communication system of any of clauses 1 through 5, wherein the first receive variable low IF (VLIF) signal is provided to a polyphase filter (PPF) and a real low pass filter.

7. The communication system of clause 3, wherein the single band signal has a bandwidth up to two times the maximum signal path bandwidth and is downconverted using the first LO1 signal and the second LO2 signal to first and second IF signals having up to the maximum signal path bandwidth each.

8. The communication system of any of clauses 1 through 7, wherein the receive radio frequency (RF) conversion stage and the receive variable IF conversion stage are located in a single integrated circuit (IC) configured to process mmW signals and the third conversion stage is located in a separate IC configured to process intermediate frequency (IF) signals.

9. A method for processing communication signals, comprising: converting, at a millimeter wave integrated circuit (mmW-IC), a receive communication signal between RF and a first receive IF using a first local oscillator (LO1) signal generated by an integer-N phase locked loop (PLL) circuit; converting, at the mmW-IC, the first receive IF signal to a first receive variable low IF (VLIF) signal using a second local oscillator (LO2) signal generated by a fractional-N phase locked loop (PLL) circuit; and converting, in an intermediate frequency integrated circuit (IFIC) the first receive variable low IF (VLIF) signal using a third local oscillator (LO3) signal generated by a second fractional-N phase locked loop (PLL) circuit.

10. The method of clause 9, further comprising: downconverting a single band signal having a bandwidth less than a maximum signal path bandwidth using the first LO1 signal and the second LO2 signal; and conveying the downconverted signal to the IFIC over one of two intermediate frequency (IF) cables.

11. The method of clause 10, further comprising: downconverting a single band signal having a bandwidth greater than a maximum signal path bandwidth using the first LO1 signal and the second LO2 signal; and conveying the downconverted signal to the IFIC over two intermediate frequency (IF) cables.

12. The method of clause 10, further comprising: downconverting an inter-band carrier aggregation (CA) band signal using the first LO1 signal and the second LO2 signal; and conveying the downconverted signal to the IFIC over two intermediate frequency (IF) cables.

13. The method of any of clauses 9 through 12, wherein multiple receive paths for performing downconversion use a common LO1 signal and a common LO2 signal.

14. The method of any of clauses 9 through 13, further comprising processing the LO2 downconverted signal in a polyphase filter (PPF) and a real low pass filter.

15. The method of clause 11, wherein the single band signal having a bandwidth up to two times the maximum signal path bandwidth is downconverted using the first LO1 signal and the second LO2 signal to first and second IF signals having up to the maximum signal path bandwidth each.

16. A communication system, comprising: a radio frequency (RF) receive section having a plurality of RF receive paths, each RF receive path having an RF conversion stage and an intermediate frequency (IF) conversion stage, the RF receive section capable of downconverting a receive signal using one or more of the plurality of RF receive paths, wherein a first PLL provides a first LO signal and a second PLL provides a second LO signal, the first LO signal comprising an RF conversion frequency and the second LO signal comprising a very low intermediate frequency (VLIF) conversion frequency; and an IF receive section having a plurality of IF receive paths, each IF receive path having a baseband conversion stage, the IF receive section capable of downconverting the receive signal using one or more of the plurality of IF receive paths, wherein a third PLL provides a third LO signal, the third LO signal comprising a near-baseband conversion frequency.

17. The communication system of clause 16, wherein the first PLL and the second PLL are integer-N PLLs.

18. The communication system of clause 16, wherein the first PLL is an integer-N PLL and the second PLL is a fractional-N PLL.

19. The communication system of any of clauses 16 through 18, wherein a first receive signal is downconverted by a first of the plurality of RF receive paths and a first of the plurality of IF receive paths and conveyed between the RF receive section and the IF receive section in a first IF cable; and a second receive signal is downconverted by a second of the plurality of RF receive paths and a second of the plurality of IF receive paths and conveyed between the RF receive section and the IF receive section in a second IF cable.

20. The communication system of any of clauses 16 through 19, wherein each of the plurality of RF receive paths and IF receive paths has a maximum signal path bandwidth, and when a receive signal has a bandwidth smaller than the maximum signal path bandwidth, the receive signal is processed by one of the plurality of RF receive paths and one of the plurality of IF receive paths.

21. The communication system of any of clauses 16 through 20, wherein each of the plurality of RF receive paths and IF receive paths has a maximum signal path bandwidth, and when a receive signal has a bandwidth larger than the maximum signal path bandwidth, the receive signal is processed by two of the plurality of RF receive paths and two of the plurality of IF receive paths.

The circuit architecture described herein described herein may be implemented on one or more ICs, analog ICs, RFICs, mixed-signal ICs, ASICs, printed circuit boards (PCBs), electronic devices, etc. The circuit architecture described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

Although selected aspects have been illustrated and described in detail, it will be understood that various substitutions and alterations may be made therein without departing from the spirit and scope of the present invention, as defined by the following claims.

What is claimed is:

1. A variable low intermediate frequency (VLIF), millimeter wave (mmW) communication system, comprising:
a receive section having a receive radio frequency (RF) conversion stage, the receive RF conversion stage configured to convert a receive communication signal between RF and a first receive IF using a first local oscillator (LO1) signal generated by an integer-N phase locked loop (PLL) circuit;
a receive variable intermediate frequency (IF) conversion stage, the receive variable IF conversion stage configured to convert the first receive IF signal to a first receive variable low IF (VLIF) signal using a second local oscillator (LO2) signal generated by one of the integer-N PLL circuit or a fractional-N phase locked loop (PLL) circuit; and
a third conversion stage configured to convert the first receive variable low IF (VLIF) signal to a near-baseband signal using a third local oscillator (LO3) signal generated by a second fractional-N PLL circuit.

2. The communication system of claim 1, wherein a single band signal having a bandwidth less than a maximum signal path bandwidth is downconverted using the first LO1 signal and the second LO2 signal and conveyed to the third conversion stage over one of two intermediate frequency (IF) cables.

3. The communication system of claim 1, wherein a single band signal having a bandwidth greater than a maximum signal path bandwidth is downconverted using the first LO1 signal and the second LO2 signal and conveyed to the third conversion stage over two intermediate frequency (IF) cables.

4. The communication system of claim 1, wherein an inter-band carrier aggregation (CA) band signal is downconverted using the first LO1 signal and the second LO2 signal and conveyed to the third conversion stage over two intermediate frequency (IF) cables.

5. The communication system of claim 1, wherein multiple receive paths for performing the RF conversion stage and the variable IF conversion stage use a common LO1 signal and a common LO2 signal.

6. The communication system of claim 1, wherein the first receive variable low IF (VLIF) signal is provided to a polyphase filter (PPF) and a real low pass filter.

7. The communication system of claim 3, wherein the single band signal has a bandwidth up to two times the maximum signal path bandwidth and is downconverted using the first LO1 signal and the second LO2 signal to first and second IF signals having up to the maximum signal path bandwidth each.

8. The communication system of claim 1, wherein the receive radio frequency (RF) conversion stage and the receive variable IF conversion stage are located in a single integrated circuit (IC) configured to process mmW signals and the third conversion stage is located in a separate IC configured to process intermediate frequency (IF) signals.

9. A method for processing communication signals, comprising:
converting, at a millimeter wave integrated circuit (mmW-IC), a receive communication signal between RF and a first receive IF using a first local oscillator (LO1) signal generated by an integer-N phase locked loop (PLL) circuit;
converting, at the mmW-IC, the first receive IF signal to a first receive variable low IF (VLIF) signal using a second local oscillator (LO2) signal generated by a fractional-N phase locked loop (PLL) circuit; and
converting, in an intermediate frequency integrated circuit (IFIC) the first receive variable low IF (VLIF) signal using a third local oscillator (LO3) signal generated by a second fractional-N phase locked loop (PLL) circuit.

10. The method of claim 9, further comprising:
downconverting a single band signal having a bandwidth less than a maximum signal path bandwidth using the first LO1 signal and the second LO2 signal; and
conveying the downconverted signal to the IFIC over one of two intermediate frequency (IF) cables.

11. The method of claim 10, further comprising:
downconverting a single band signal having a bandwidth greater than a maximum signal path bandwidth using the first LO1 signal and the second LO2 signal; and
conveying the downconverted signal to the IFIC over two intermediate frequency (IF) cables.

12. The method of claim 10, further comprising:
downconverting an inter-band carrier aggregation (CA) band signal using the first LO1 signal and the second LO2 signal; and
conveying the downconverted signal to the IFIC over two intermediate frequency (IF) cables.

13. The method of claim 9, wherein multiple receive paths for performing downconversion use a common LO1 signal and a common LO2 signal.

14. The method of claim 9, further comprising processing the LO2 downconverted signal in a polyphase filter (PPF) and a real low pass filter.

15. The method of claim 11, wherein the single band signal having a bandwidth up to two times the maximum signal path bandwidth is downconverted using the first LO1 signal and the second LO2 signal to first and second IF signals having up to the maximum signal path bandwidth each.

16. A communication system, comprising:
a radio frequency (RF) receive section having a plurality of RF receive paths, each RF receive path having an RF conversion stage and an intermediate frequency (IF) conversion stage, the RF receive section capable of downconverting a receive signal using one or more of the plurality of RF receive paths, wherein a first PLL provides a first LO signal and a second PLL provides a second LO signal, the first LO signal comprising an RF conversion frequency and the second LO signal comprising a very low intermediate frequency (VLIF) conversion frequency; and
an IF receive section having a plurality of IF receive paths, each IF receive path having a baseband conversion stage, the IF receive section capable of downconverting the receive signal using one or more of the plurality of IF receive paths, wherein a third PLL provides a third LO signal, the third LO signal comprising a near-baseband conversion frequency.

17. The communication system of claim 16, wherein the first PLL and the second PLL are integer-N PLLs.

18. The communication system of claim 16, wherein the first PLL is an integer-N PLL and the second PLL is a fractional-N PLL.

19. The communication system of claim 16, wherein a first receive signal is downconverted by a first of the plurality of RF receive paths and a first of the plurality of IF receive paths and conveyed between the RF receive section and the IF receive section in a first IF cable; and
a second receive signal is downconverted by a second of the plurality of RF receive paths and a second of the plurality of IF receive paths and conveyed between the RF receive section and the IF receive section in a second IF cable.

20. The communication system of claim 16, wherein each of the plurality of RF receive paths and IF receive paths has a maximum signal path bandwidth, and when a receive signal has a bandwidth smaller than the maximum signal path bandwidth, the receive signal is processed by one of the plurality of RF receive paths and one of the plurality of IF receive paths.
